(19) United States
(12) Patent Application Publication
(10) Pub. No.: US 2024/0321804 A1
(43) Pub. Date: Sep. 26, 2024

(54) SEMICONDUCTOR PACKAGE INCLUDING REDISTRIBUTION STRUCTURE AND METHOD OF MANUFACTURING THE SAME

(71) Applicant: Samsung Electronics Co., Ltd., Suwon-si (KR)

(72) Inventors: Dowan Kim, Suwon-si (KR); Jieun Woo, Suwon-si (KR); Unbyoung Kang, Suwon-si (KR); Seokbong Park, Suwon-si (KR)

(21) Appl. No.: 18/489,886

(22) Filed: Oct. 19, 2023

(30) Foreign Application Priority Data
Mar. 24, 2023 (KR) 10-2023-0039168
Apr. 28, 2023 (KR) 10-2023-0056639

(51) Int. Cl. H01L 23/00; H01L 21/56; H01L 23/31; H01L 25/18; H10B 80/00

(52) U.S. Cl. CPC H01L 24/20; H01L 21/568; H01L 23/3128; H01L 24/16; H01L 24/19; H01L 25/18; H10B 80/00; H01L 2224/16227; H01L 2224/19; H01L 2224/2101; H01L 2224/215; H01L 2224/2201; H01L 2924/01004; H01L 2924/01012; H01L 2924/01013; H01L 2924/01022; H01L 2924/01024; H01L 2924/01025; H01L 2924/01027; H01L 2924/01028; H01L 2924/01029; H01L 2924/01031; H01L 2924/01042; H01L 2924/01044; H01L 2924/01049; H01L 2924/0105; H01L 2924/01073; H01L 2924/01074; H01L 2924/01075; H01L 2924/0132; H01L 2924/04941; H01L 2924/04953; H01L 2924/1431; H01L 2924/1432; H01L 2924/1433; H01L 2924/14361; H01L 2924/1437; H01L 2924/1441; H01L 2924/1443

(57) ABSTRACT

A semiconductor package a first package unit comprising a semiconductor chip; and a redistribution structure on the first package unit, wherein the redistribution structure comprises a plurality of wiring lines and a plurality of insulating layers on the plurality of wiring lines, wherein the plurality of wiring lines comprise first subset including a plurality of outermost wiring lines and a second subset, wherein a vertical distance between the plurality of outermost wiring lines and the first package unit is greater than a vertical distance between the second subset of the plurality of wiring lines and the first package unit, a respective surface roughness of each of the plurality of outermost wiring lines is different, and the respective surface roughness of each of the plurality of outermost wiring lines is based on a respective width of each of the plurality of outermost wiring lines in a horizontal direction.

### CROSS-REFERENCE TO RELATED APPLICATIONS

This application is based on and claims priority under 35 U.S.C. § 119 to Korean Patent Application No. 10-2023-0039168, filed on Mar. 24, 2023, and Korean Patent Application No. 10-2023-0056639, filed on Apr. 28, 2023, in the Korean Intellectual Property Office, the disclosures of which are incorporated by reference herein in their entirety.

### TECHNICAL FIELD

The present disclosure relates to a semiconductor package and a method of manufacturing the semiconductor package, and more particularly, to a semiconductor package including a redistribution structure and a method of manufacturing the semiconductor package.

### BACKGROUND

Due to the advance of electronics technology, electronic devices have been reduced in size, become multifunctional, and increased in capacity. Therefore, for highly integrated semiconductor chips in which the number of connection terminals for input/output (I/O) of data is increased, semiconductor packages including redistribution structures have been developed. As wiring lines of redistribution structures have various linewidths and as the minimum linewidths in wiring lines decrease, it may be desirable to develop a technique of securing the reliability of wiring lines having various linewidths in redistribution structures.

### SUMMARY

The present disclosure provides a semiconductor package having improved reliability because the semiconductor package may secure the minimum dimension for wiring lines of a redistribution structure and has a structure capable of securing the adhesion between the wiring lines and an insulating structure covering the wiring lines, even when the wiring lines have various linewidths and the minimum line width in the wiring lines decreases.

The present disclosure also provides a method of manufacturing a semiconductor package, which may secure the minimum dimension for wiring lines of a redistribution structure and may have improved reliability by securing the adhesion between the wiring lines and an insulating structure covering the wiring lines, even when the wiring lines have various linewidths and the minimum linewidth in the wiring lines decreases.

According to an aspect of the present disclosure, a semiconductor package comprises a first package unit comprising a semiconductor chip; and a redistribution structure on the first package unit, wherein the redistribution structure comprises a plurality of wiring lines and a plurality of insulating layers on the plurality of wiring lines, wherein the plurality of wiring lines comprise first subset including a plurality of outermost wiring lines and a second subset, wherein a vertical distance between the plurality of outermost wiring lines and the first package unit is greater than a vertical distance between the second subset of the plurality of wiring lines and the first package unit, a respective surface roughness of each of the plurality of outermost wiring lines is different, and the respective surface roughness of each of the plurality of outermost wiring lines is based on a respective width of each of the plurality of outermost wiring lines in a horizontal direction.

According to another aspect of the present disclosure, a semiconductor package comprises: a package unit comprising a semiconductor chip that comprises a first surface and a second surface that is opposite to the first surface; a frontside redistribution structure on the first surface of the semiconductor chip; and a backside redistribution structure on the second surface of the semiconductor chip, wherein each of the frontside redistribution structure and the backside redistribution structure comprises: a plurality of wiring lines and a plurality of insulating layers on the plurality of wiring lines, wherein the plurality of wiring lines comprise a first subset comprising a plurality of outermost wiring lines and a second subset, wherein a vertical distance between the plurality of outermost wiring lines and the package unit is greater than a vertical distance between the second subset of the plurality of wiring lines and the package unit, a respective surface roughness of each of the plurality of outermost wiring lines is different, and the respective surface roughness of each of the plurality of outermost wiring lines is based on a respective width of each of the plurality of outermost wiring lines in a horizontal direction.

According to another aspect of the present disclosure, a semiconductor package comprises a first package unit comprising a semiconductor chip that comprises an active surface and an inactive surface that is opposite to the active surface; a frontside redistribution structure on the active surface of the semiconductor chip; a backside redistribution structure on the inactive surface of the semiconductor chip; and a second package unit on the backside redistribution structure, wherein at least one of the frontside redistribution structure and the backside redistribution structure comprises: a plurality of wiring lines and a plurality of insulating layers on the plurality of wiring lines, wherein the plurality of wiring lines comprise a plurality of outermost wiring lines and a plurality of inner wiring lines, wherein a vertical distance between the plurality of outermost wiring lines and the first package unit is greater than a vertical distance between the plurality of inner lines and the first package unit, a respective surface roughness of each of the plurality of inner wiring lines is independent of a respective width of the plurality of inner wiring lines in a horizontal direction, and a respective surface roughness of each of the plurality of outermost wiring lines is based on a respective width of each of the plurality of outermost wiring lines in the horizontal direction.

According to another aspect of the present disclosure, a method of manufacturing a semiconductor package includes forming a package unit comprising a semiconductor chip; and forming a redistribution structure on the package unit, wherein the forming of the redistribution structure comprises: forming a plurality of inner wiring lines on the package unit; forming an inner insulating layer on the plurality of inner wiring lines; forming a plurality of outermost preliminary wiring lines on the inner insulating layer, wherein each of the plurality of outermost preliminary wiring lines comprise different respective widths from each other in a horizontal direction; forming a local insulating pattern on a first wiring line portion of the plurality of outermost preliminary wiring lines, wherein the first wiring line portion comprises a first width in the horizontal direction; increasing a surface roughness of a preliminary second wiring line portion of the plurality of outermost preliminary wiring lines to form a second wiring line portion, wherein the preliminary second wiring line portion comprises a second width that is greater than the first width of the first wiring line portion in the horizontal direction, wherein the surface roughness of the preliminary second wiring line portion is increased while local insulating pattern is on the first wiring line portion and while the preliminary second wiring line portion is exposed; and forming an outer insulating pattern that is on the plurality of outermost preliminary wiring lines and that is connected the local insulating pattern and the second wiring line portion, wherein the outer insulating pattern and the local insulating pattern comprise different materials.

### BRIEF DESCRIPTION OF THE DRAWINGS

Embodiments will be more clearly understood from the following detailed description taken in conjunction with the accompanying drawings in which:

FIG. 1A is a cross-sectional view illustrating a semiconductor package according to some embodiments of the present disclosure;

FIG. 1B is an enlarged cross-sectional view of the region EX1 of FIG. 1A;

FIG. 2 is a plan view illustrating a semiconductor package according to some embodiments of the present disclosure;

FIG. 3 is a cross-sectional view illustrating a semiconductor package according to some embodiments of the present disclosure;

FIG. 4 is a cross-sectional view illustrating a semiconductor package according to some embodiments of the present disclosure;

FIG. 5 is a cross-sectional view illustrating a semiconductor package according to some embodiments of the present disclosure;

FIG. 6 is a cross-sectional view illustrating a semiconductor package according to some embodiments of the present disclosure;

FIGS. 7A, 7B, 7C, 7D, 7E, 7F, 7G, 7H, 7I, 7J, 7K, 7L, and 7N are cross-sectional views illustrating a sequence of processes of a method of manufacturing a semiconductor package according to some embodiments of the present disclosure; and

FIGS. 8A, 8B, 8C, 8D, 8E, 8F, and 8G are cross-sectional views illustrating a sequence of processes of a method of manufacturing a semiconductor package according to some embodiments of the present disclosure.

### DETAILED DESCRIPTION OF THE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. As used herein, “an element A is at a same level as element B” refers to at least one surface of element A that is coplanar with at least one surface of element B in a given direction.

Hereinafter, embodiments of the present disclosure will be described in detail with reference to the accompanying drawings. Like components are denoted by like reference numerals throughout the specification, and repeated descriptions thereof are omitted.

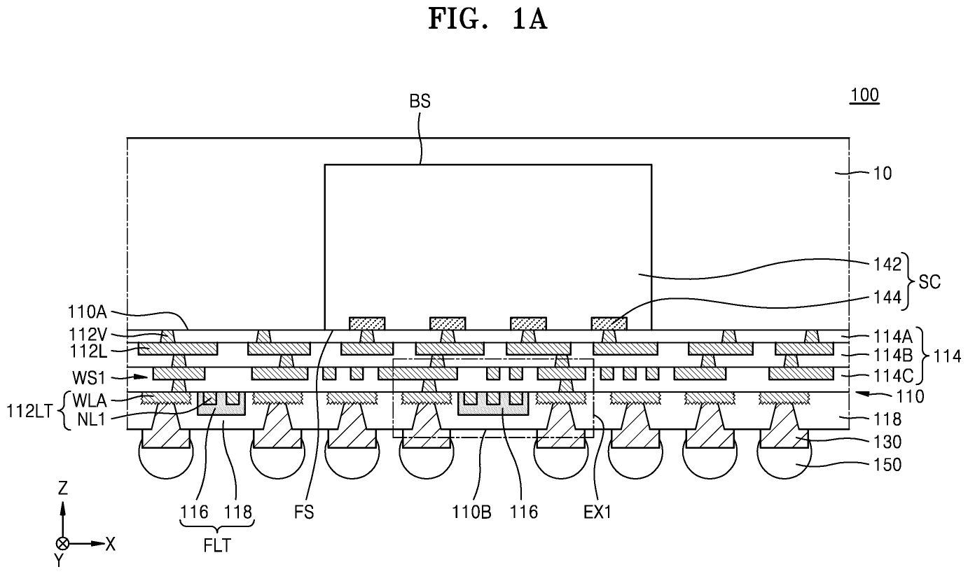

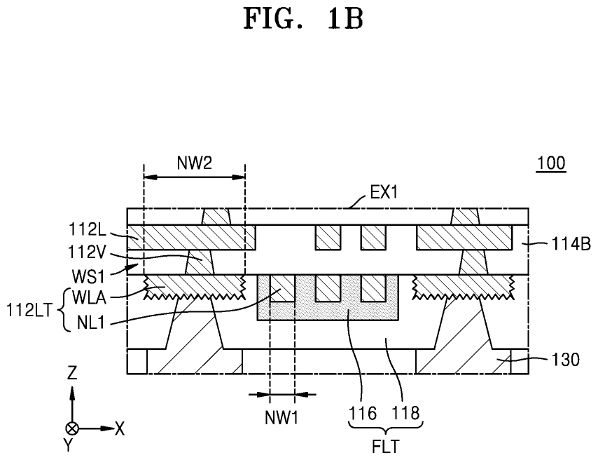

FIG. 1A is a cross-sectional view illustrating a semiconductor package 100 according to some embodiments of the present disclosure. FIG. 1B is an enlarged cross-sectional view of the region EX1 of FIG. 1A.

Referring to FIGS. 1A and 1i, the semiconductor package 100 may include a package unit 10, which includes a semiconductor chip SC, and a frontside redistribution structure 110, which is on the package unit 10.

The semiconductor chip SC may include a semiconductor device 142 and a plurality of chip pads 144 arranged on one surface of the semiconductor device 142. The frontside redistribution structure 110 may have a first surface 110A and a second surface 110B, which are opposite to each other. The plurality of chip pads 144 of the semiconductor chip SC may be bonded to the first surface 110A of the frontside redistribution structure 110. The plurality of chip pads 144 may be connected to a first wiring structure WS1, which is included in the frontside redistribution structure 110. A surface of the semiconductor chip SC at which the plurality of chip pads 144 are exposed may constitute an active surface FS of the semiconductor chip SC, and an opposite surface of the active surface FS may constitute an inactive surface BS of the semiconductor chip SC.

The first wiring structure WS1 of the frontside redistribution structure 110 may include a plurality of wiring lines 112LT and 112L and a plurality of conductive via patterns 112V respectively connected to the plurality of wiring lines 112LT, the plurality of wiring lines 112LT and 112L being respectively arranged at a plurality of vertical levels having different distances from each other in the vertical direction (Z direction) from the package unit 10. The plurality of wiring lines 112LT and 112L may include a plurality of outermost wiring lines 112LT arranged at the outermost vertical level, which has the greatest vertical distance (e.g., a distance in the vertical direction (Z-direction)) from the package unit 10 from among the plurality of vertical levels, and a plurality of inner wiring lines 112L arranged between the package unit 10 and the plurality of outermost wiring lines 112LT. The vertical distance between the package unit 10 and each of the plurality of inner wiring lines 112L may be less than the vertical distance between the package unit 10 and each of the plurality of outermost wiring lines 112LT.

The frontside redistribution structure 110 may include a plurality of insulating layers FLT and 114 respectively on and/or covering the plurality of wiring lines 112LT and 112L. The plurality of insulating layers FLT and 114 may include an outermost insulating layer FLT, which is on and/or covers the outermost wiring lines 112LT, and a plurality of inner insulating layers 114, which are on and/or cover the plurality of inner wiring lines 112L.

The plurality of inner insulating layers 114 may include a first inner insulating layer 114A, a second inner insulating layer 114B, and a third inner insulating layer 114C, which are stacked in the stated order on the package unit 10. Each of the first inner insulating layer 114A, the second inner insulating layer 114B, and the third inner insulating layer 114C may cover the plurality of inner wiring lines 112L arranged at one vertical level and between the package unit 10 and the outer insulating layer FLT. Each of the first inner insulating layer 114A, the second inner insulating layer 114B, and the third inner insulating layer 114C may include a single layer.

The plurality of outermost wiring lines 112LT may each have a different surface roughness based on the respective widths of the plurality of outermost wiring lines 112LT in the horizontal direction (for example, the X direction in FIG. 1A). The plurality of outermost wiring lines 112LT may include a plurality of first wiring line portions NL1, which each have a first minimum width NW1 in the horizontal direction (for example, the X direction in FIG. 1A), and a plurality of second wiring line portions WLA, which each have a second minimum width NW2 that is greater than the first minimum width NW1 of each first wiring line portion NL1 in the horizontal direction. In the plurality of outermost wiring lines 112LT, the surface roughness of at least a portion of each of the plurality of second wiring line portions WLA may be greater than the surface roughness of each of the plurality of first wiring line portions NL1.

In some embodiments, in the plurality of outermost wiring lines 112LT, the first minimum width NW1 of each of the plurality of first wiring line portions NL1 may be 10 μm or less. For example, the first minimum width NW1 of each of the plurality of first wiring line portions NL1 may be selected from, but is not limited to, a range of about 5 μm to about 10 μm. In some embodiments, in the plurality of outermost wiring lines 112LT, the second minimum width NW2 of each of the plurality of second wiring line portions WLA may be greater than 10 μm. For example, the second minimum width NW2 of each of the plurality of second wiring line portions WLA may be selected from, but is not limited to, a range that is greater than about 10 μm and less than or equal to about 200 μm. In some embodiments, in the plurality of outermost wiring lines 112LT, the thickness of each of the plurality of first wiring line portions NL1 and the plurality of second wiring line portions WLA may be, but is not limited to, about 0.5 μm to about 20 μm. Herein, in the plurality of outermost wiring lines 112LT, each of the plurality of first wiring line portions NL1 may be referred to as a narrow wiring line portion and each of the plurality of second wiring line portions WLA may be referred to as a wide wiring line portion.

In the plurality of outermost wiring lines 112LT, a first surface of each of the plurality of first wiring line portions NL1, which contacts the outermost insulating layer FLT, may have a first surface roughness, and a second surface of each of the plurality of second wiring line portions WLA, which contacts the outermost insulating layer FLT, may have a second surface roughness that is greater than the first surface roughness of each first wiring line portion NL1. In some embodiments, the first surface roughness of each of the plurality of first wiring line portions NL1 may be 0.1 μm or less, for example, about 0 μm to about 0.1 μm, and the second surface roughness of each of the plurality of second wiring line portions WLA may have a value that is selected from a range of about 0.1 μm to about 0.6 μm and greater than the first surface roughness of each first wiring line portion NL1. As used herein, the term “surface roughness” refers to an arithmetic average roughness (Ra).

In some embodiments, the surface roughness of each of the plurality of inner wiring lines 112L may be 0.1 μm or less and is independent of the respective widths of the plurality of inner wiring lines 112L in the horizontal direction.

In the frontside redistribution structure 110, each of the plurality of inner wiring lines 112L, the plurality of conductive via patterns 112V, and the plurality of outermost wiring lines 112LT may include copper (Cu), titanium (Ti), titanium tungsten (TiW), titanium nitride (TiN), tantalum (Ta), tantalum nitride (TaN), chromium (Cr), aluminum (Al), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or a combination thereof.

The outermost insulating layer FLT may include a local insulating pattern 116, which is on and/or covers the plurality of first wiring line portions NL1 from among the plurality of outermost wiring lines 112LT at the same vertical level having the same vertical distance from the package unit 10. The outermost insulating layer FLT may include an outer insulating pattern 118, which is spaced apart from the plurality of first wiring line portions NL1 with the local insulating pattern 116 therebetween. The local insulating pattern 116 may contact the surface of each of the plurality of first wiring line portions NL1 but may not contact the surface of each of the plurality of second wiring line portions WLA. The outer insulating pattern 118 may contact each of the local insulating pattern 116 and the plurality of second wiring line portions WLA.

A portion of the outermost insulating layer FLT, which is on and/or covers a first wiring line portion NL1, may include a double-layered structure, and a portion of the outermost insulating layer FLT, which is on and/or covers the plurality of second wiring line portions WLA, may include a single-layered structure. The portion of the outermost insulating layer FLT that is on and/or covers the first wiring line portion NL1 may have a double-layered structure including the local insulating pattern 116 and the outer insulating pattern 118. The portion of the outermost insulating layer FLT that is on and/or covers the plurality of second wiring line portions WLA may have a single-layered structure including the outer insulating pattern 118.

In some embodiments, each of the first inner insulating layer 114A, the second inner insulating layer 114B, and the third inner insulating layer 114C may have a single-layered structure including at least one selected from a photo-imageable dielectric (PID), Ajinomoto Build-up Film (ABF), a solder resist (SR), an epoxy molding compound (EMC), FR-4, and bismaleimide triazine (BT).

The local insulating pattern 116 and the outer insulating pattern 118 may respectively include organic insulating films including different materials from each other. In some embodiments, when the plurality of outermost wiring lines 112LT have the same surface roughness, the local insulating pattern 116 may include a material providing better adhesion with respect to the plurality of outermost wiring lines 112LT than a constituent material of the outer insulating pattern 118. In some embodiments, the local insulating pattern 116 and the outer insulating pattern 118 may respectively include different materials selected from a PID, ABF, an SR, an EMC, FR-4, and BT. For example, the local insulating pattern 116 may include a PID material layer or an SR layer, and the outer insulating pattern 118 may include at least one selected from ABF, an SR, a PID, and an EMC. In some embodiments, the local insulating pattern 116 and the outer insulating pattern 118 may respectively include PID material layers, which include different components from each other. For example, the local insulating pattern 116 and the outer insulating pattern 118 may respectively include different materials selected from polyhydroxyamide (PHA), polybenzoxazole (PBO), polyamic acid (PAA), polyimide (PI), a benzocyclobutene (BCB)-based polymer, bisphenol-A (BPA) epoxy, and novolac epoxy.

As shown in FIG. 1A, the semiconductor chip SC may be attached onto the frontside redistribution structure 110 such that the plurality of chip pads 144 are on the frontside redistribution structure 110. The plurality of chip pads 144 of the semiconductor chip SC may be connected to at least one outermost wiring line 112LT selected from the first wiring structure WS1 of the frontside redistribution structure 110.

A plurality of conductive pads 130 may be arranged on the second surface 110B of the frontside redistribution structure 110. Each of the plurality of conductive pads 130 may be connected to one outermost wiring line 112LT selected from the plurality of outermost wiring lines 112LT. Each of the plurality of conductive pads 130 may contact a surface of one outermost wiring line 112LT selected from the plurality of outermost wiring lines 112LT. The surface of each of the plurality of outermost wiring lines 112LT that contacts a conductive pad 130 may have a surface roughness selected from a range of about 0.1 μm to about 0.6 μm. The plurality of conductive pads 130 may not contact the plurality of first wiring line portions NL1. In some embodiments, the conductive pad 130 may include an under bump metallurgy (UBM) layer, which includes Ni, Ti, TiW, Au, Al, Ni, NiV, Cr, Cu, or a combination thereof, but a constituent material of the conductive pad 130 is not limited to the examples set forth above.

A plurality of external connection terminals 150 may be respectively arranged on the plurality of conductive pads 130 on the second surface 110B of the frontside redistribution structure 110. Each of the plurality of external connection terminals 150 may contact one conductive pad 130 selected from the plurality of conductive pads 130. In some embodiments, each of the plurality of external connection terminals 150 may include, but is not limited to, Sn, Ag, Cu, Ni, or a combination thereof. In some embodiments, each of the plurality of external connection terminals 150 may include, but is not limited to, a solder ball.

The semiconductor chip SC may include a semiconductor substrate. The semiconductor substrate may include a semiconductor element, such as Si or Ge, or a compound semiconductor, such as SiC, GaAs, InAs, or InP. The semiconductor chip SC may include a plurality of individual devices of various types.

The semiconductor chip SC may be configured to receive an external signal, such as at least one of a control signal, a power signal, a ground signal for the operation of the semiconductor chip SC through a chip pad 144, the frontside redistribution structure 110, and the conductive pad 130, and/or a data signal to be stored in the semiconductor chip SC. The semiconductor chip SC may also provide data stored in the semiconductor chip SC to an external device.

In some embodiments, the semiconductor chip SC may include a logic chip or a memory chip. The logic chip may include a microprocessor. For example, the logic chip may include a central processing unit (CPU), a controller, an application-specific integrated circuit (ASIC), or the like. The memory chip may include a volatile memory chip, such as dynamic random access memory (DRAM) or static random access memory (SRAM), or a non-volatile memory chip, such as phase-change random access memory (PRAM), magnetoresistive random access memory (MRAM), ferroelectric random access memory (FeRAM), or resistive random access memory (RRAM). In some embodiments, the memory chip may include a high bandwidth memory (HBM) DRAM semiconductor chip.

In some embodiments, the semiconductor chip SC may include a system-on-chip (SoC) type application processor (AP) chip, which is used in a mobile system, for example, a mobile phone, an MP3 player, a navigation system, a portable multimedia player (PMP), or the like, or a double data rate (DDR) synchronous dynamic random access memory (SDRAM) chip (referred to as a “DDR chip” hereinafter) used in a mobile system.

According to the semiconductor package 100 described with reference to FIGS. 1A and 1i, the plurality of outermost wiring lines 112LT of the frontside redistribution structure 110 may include the plurality of first wiring line portions NL1, which each have the first minimum width NW1 that is relatively small, and the plurality of second wiring line portions WLA, which each have the second minimum width NW2 that is greater than the first minimum width NW1 of each first wiring line portion NL1. The surface roughness of each of the plurality of second wiring line portions WLA may be greater than the surface roughness of each of the plurality of first wiring line portions NL1. Therefore, the adhesion between the plurality of second wiring line portions WLA and the outer insulating pattern 118 may improve. In addition, when chemical and/or physical treatment is applied to the surface of each of the plurality of second wiring line portions WLA, the plurality of first wiring line portions NL1, which each have the first minimum width NW1 that is relatively small, may be covered and protected by the local insulating pattern 116. Therefore, even when the linewidth of each of the plurality of first wiring line portions NL1, which each have the first minimum width NW1 that is relatively small, is reduced because the semiconductor package 100 is highly integrated and reduced in size, the plurality of first wiring line portions NL1 may be inhibited from defects, such as collapse or lifting, due to a reduction in the linewidths of the plurality of first wiring line portions NL1 while the chemical and/or physical treatment is applied to the surface of each of the plurality of second wiring line portions WLA. Furthermore, the adhesion between the plurality of first wiring line portions NL1 and the local insulating pattern 116 and the adhesion between the plurality of second wiring line portions WLA and the outer insulating pattern 118 may be secured. Therefore, even when the plurality of outermost wiring lines 112LT of the frontside redistribution structure 110 respectively have various linewidths and the minimum linewidth in the plurality of outermost wiring lines 112LT is reduced, the minimum dimension for the plurality of outermost wiring lines 112LT may be secured. In addition, the adhesion required between each of the plurality of outermost wiring lines 112LT and the outermost insulating layer FLT covering each thereof may be secured, thereby improving the reliability and manufacturing process efficiency of the semiconductor package 100.

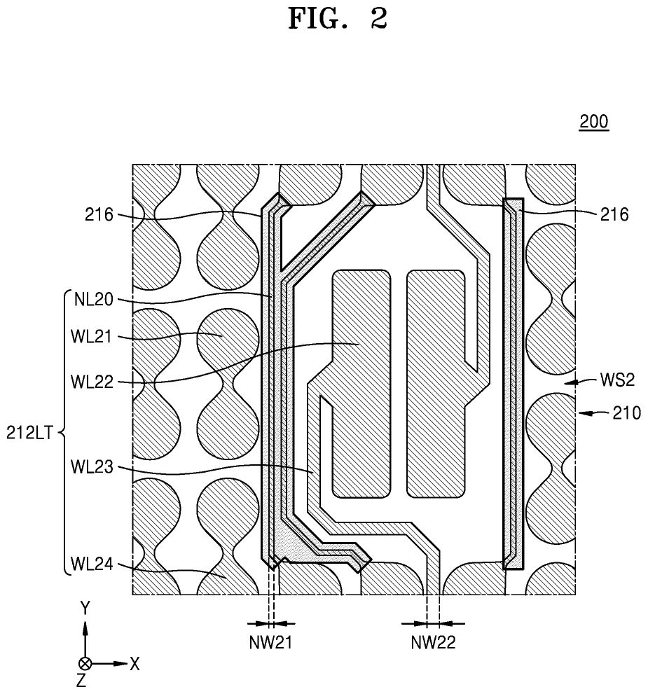

FIG. 2 is a plan view illustrating a semiconductor package 200 according to some embodiments. In FIG. 2, the same reference numerals shown in FIGS. 1A and 1B respectively denote the same members, and here, repeated descriptions thereof are omitted.

Referring to FIG. 2, the semiconductor package 200 has substantially the same configuration as the semiconductor package 100 described with reference to FIGS. 1A and 1B. However, the semiconductor package 200 includes a frontside redistribution structure 210 including a wiring structure WS2. The wiring structure WS2 and the frontside redistribution structure 210 have substantially the same configurations as the first wiring structure WS1 and the frontside redistribution structure 110, which are described with reference to FIGS. 1A and 1, respectively. However, the wiring structure WS2 of the frontside redistribution structure 210 may include a plurality of outermost wiring lines 212LT.

The plurality of outermost wiring lines 212LT may include a plurality of first and second wiring line portions NL20, WL21, WL22, WL23, and WL24, which have various linewidths in the horizontal direction (for example, the X direction or the Y direction in FIG. 2) and have various planar shapes. The plurality of first and second wiring line portions NL20, WL21, WL22, WL23, and WL24 may include a plurality of first wiring line portions NL20, which have relatively small widths in the horizontal direction, and a plurality of second wiring line portions WL21, WL22, WL23, and WL24, which have relatively larger/greater widths in the horizontal direction. For example, in the plurality of outermost wiring lines 212LT, a first wiring line portion NL20 may have a first minimum width NW21 in the horizontal direction, and a second wiring line portion WL23 may have a second minimum width NW22 that is greater than the first minimum width NW21 of the first wiring line portion NL20 in the horizontal direction.

In the semiconductor package 200, a local insulating pattern 216, which is on and/or covers some of the outermost wiring lines 212LT, may cover the plurality of first wiring line portions NL20 and may not cover the plurality of second wiring line portions WL21, WL22, WL23, and WL24. Each of the local insulating pattern 216 and the plurality of second wiring line portions WL21, WL22, WL23, and WL24 may be covered by the outer insulating pattern 118 (see FIGS. 1A and 1B).

A surface of each of the plurality of first wiring line portions NL20, which contacts the local insulating pattern 216, may have a first surface roughness, and a surface of each of the plurality of second wiring line portions WL21, WL22, WL23, and WL24, which contacts the outer insulating pattern 118 (see FIGS. 1A and 1i), may have a second surface roughness that is greater than the first surface roughness of each first wiring line portion NL20. The first surface roughness of each first wiring line portion NL20 may be 0.1 μm or less, for example, about 0 μm to about 0.1 μm, and the second surface roughness of each of the second wiring line portions WL21, WL22, WL23, and WL24 may have a value that is selected from a range of about 0.1 μm to about 0.6 μm and greater than the first surface roughness of each first wiring line portion NL20. The configurations of the local insulating pattern 216 and the plurality of outermost wiring lines 212LT are the same as those of the local insulating pattern 116 and the plurality of outermost wiring lines 112LT, respectively, which are described above with reference to FIGS. 1A and 1B.

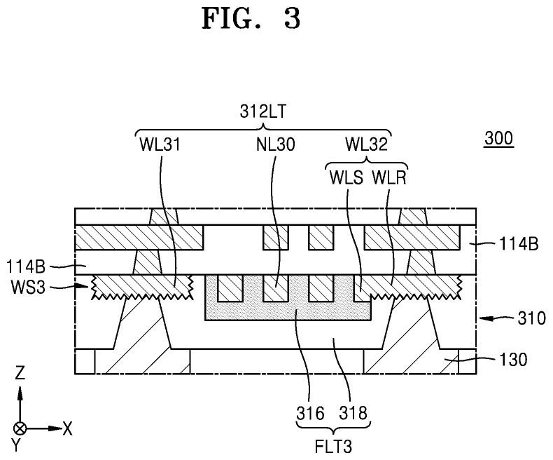

FIG. 3 is a cross-sectional view illustrating a semiconductor package 300 according to some embodiments. FIG. 3 illustrates an enlarged cross-sectional configuration of a portion of the semiconductor package 300, which corresponds to the region EX1 of FIG. 1A. In FIG. 3, the same reference numerals shown in FIGS. 1A and 1B respectively denote the same members, and here, repeated descriptions thereof are omitted.

Referring to FIG. 3, the semiconductor package 300 has substantially the same configuration as the semiconductor package 100 described with reference to FIGS. 1A and 1B. However, the semiconductor package 300 includes a frontside redistribution structure 310 including a wiring structure WS3. Detailed configurations of the wiring structure WS3 and the frontside redistribution structure 310 are substantially the same as those of the first wiring structure WS1 and the frontside redistribution structure 110, respectively, which are described with reference to FIGS. 1A and 1B. However, the frontside redistribution structure 310 may include a plurality of outermost wiring lines 312LT, which are included in the wiring structure WS3, and an outermost insulating layer FLT3 on and/or covering the plurality of outermost wiring lines 312LT.

In the frontside redistribution structure 310, each of the plurality of outermost wiring lines 312LT may have a different surface roughness from each other and is based on the respective widths of the plurality of outermost wiring lines 312LT in the horizontal direction (for example, the X direction in FIG. 3). The plurality of outermost wiring lines 312LT may include a plurality of first wiring line portions NL30, which have relatively small widths in the horizontal direction, and a plurality of second wiring line portions WL31 and WL32, which have relatively great widths in the horizontal direction. Herein, each of the plurality of first wiring line portions NL30 may be referred to as a narrow wiring line portion, and each of the plurality of second wiring line portions WL31 and WL32 may be referred to as a wide wiring line portion.

Detailed configurations of the first wiring line portions NL30 and the second wiring line portions WL31 and WL32 are substantially the same as those of the first wiring line portions NL1 and the second wiring line portions WLA, which are described above with reference to FIGS. 1A and 1B. However, the surface roughness of a portion of the second wiring line portion WL31, which contacts the outermost insulating layer FLT3, may be greater than the surface roughness of each of the plurality of first wiring line portions NL30 where the second wiring line portion WL31 corresponds to a portion of the plurality of second wiring line portions WL31 and WL32. In addition, the second wiring line portion WL32, which corresponds to another portion of the plurality of second wiring line portions WL31 and WL32, may include a first wide wiring line portion WLS, which is adjacent to the first wiring line portion NL30 in the horizontal direction, and a second wide wiring line portion WLR, which is integrally connected to the first wide wiring line portion WLS and spaced apart from the first wiring line portion NL30 with the first wide wiring line portion WLS therebetween. The surface roughness of a portion of the first wide wiring line portion WLS that contacts the outermost insulating layer FLT3 in the second wiring line portion WL32 may be equal to or similar to the surface roughness of each of the plurality of first wiring line portions NL30. The surface roughness of a portion of the second wide wiring line portion WLR that contacts the outermost insulating layer FLT3 in the second wiring line portion WL32 may be greater than the surface roughness of each of the plurality of first wiring line portions NL30. For example, the surface roughness at the surface of each of the plurality of first wiring line portions NL30 and the surface of the first wide wiring line portion WLS of the second wiring line portion WL32 may be 0.1 μm or less, for example, about 0 μm to about 0.1 μm. The surface roughness at the surface of the second wiring line portion WL31 and the surface of the second wide wiring line portion WLR of the second wiring line portion WL32 may have a value that is selected from a range of about 0.1 μm to about 0.6 μm and greater than the surface roughness at the surface of each of the plurality of first wiring line portions NL30 and the first wide wiring line portion WLS.

The outermost insulating layer FLT3 may include a local insulating pattern 316 and an outer insulating pattern 318, which are in contact with each other. The local insulating pattern 316 may be on and/or cover the plurality of first wiring line portions NL30 and the first wide wiring line portion WLS of the second wiring line portion WL32. The local insulating pattern 316 may contact the plurality of first wiring line portions NL30 and the first wide wiring line portion WLS of the second wiring line portion WL32. The outer insulating pattern 318 may be spaced apart from the plurality of first wiring line portions NL30 and the first wide wiring line portion WLS of the second wiring line portion WL32 with the local insulating pattern 316 therebetween. The outer insulating pattern 318 may contact respective surfaces of portions of the plurality of second wiring line portions WL31 and WL32 and not contact the first wide wiring line portion WLS. The surface roughness of portions of the plurality of first wiring line portions NL30 and the plurality of second wiring line portions WL31 and WL32 that contact the local insulating pattern 316 may be 0.1 μm or less, for example, about 0 μm to about 0.1 μm, and the surface roughness of portions of the plurality of second wiring line portions WL31 and WL32 that contact the outer insulating pattern 318 may have a value that is selected from a range of about 0.1 μm to about 0.6 μm and greater than the surface roughness of the portions thereof contacting the local insulating pattern 316.

In the outermost insulating layer FLT3, the local insulating pattern 316 and the outer insulating pattern 318 may include different materials from each other. The configurations of the local insulating pattern 316 and the outer insulating pattern 318 are substantially the same as those of the local insulating pattern 116 and the outer insulating pattern 118, respectively, which are described with reference to FIGS. 1A and 1B.

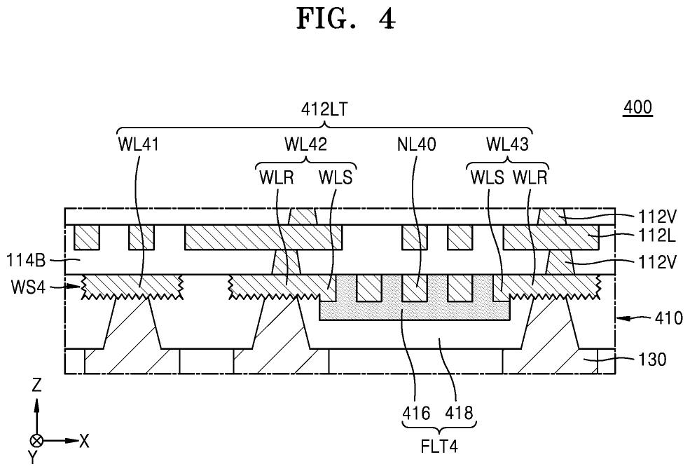

FIG. 4 is a cross-sectional view illustrating a semiconductor package 400 according to some embodiments. FIG. 4 illustrates an enlarged cross-sectional configuration of a portion of the semiconductor package 400, which corresponds to the region EX1 and some regions in FIG. 1A. In FIG. 4, the same reference numerals shown in FIGS. 1A and 1B respectively denote the same members, and here, repeated descriptions thereof are omitted.

Referring to FIG. 4, the semiconductor package 400 has substantially the same configuration as the semiconductor package 100 described with reference to FIGS. 1A and 1B. However, the semiconductor package 400 includes a frontside redistribution structure 410 including a wiring structure WS4. The configurations of the wiring structure WS4 and the frontside redistribution structure 410 are substantially the same as those of the first wiring structure WS1 and the frontside redistribution structure 110, respectively, which are described with reference to FIGS. 1A and 1B. However, the frontside redistribution structure 410 may include a plurality of outermost wiring lines 412LT, which are included in the wiring structure WS4, and an outermost insulating layer FLT4 on and/or covering the plurality of outermost wiring lines 412LT.

In the frontside redistribution structure 410, the plurality of outermost wiring lines 412LT may each have a different surface roughness from each other that is based on the respective widths of the plurality of outermost wiring lines 412LT in the horizontal direction (for example, the X direction in FIG. 4). The plurality of outermost wiring lines 412LT may include a plurality of first wiring line portions NL40, which have relatively small widths in the horizontal direction, and a plurality of second wiring line portions WL41, WL42, and WL43, which have relatively larger/greater widths in the horizontal direction. Herein, in the plurality of outermost wiring lines 412LT, each of the plurality of first wiring line portions NL40 may be referred to as a narrow wiring line portion and each of the plurality of second wiring line portions WL41, WL42, and WL43 may be referred to as a wide wiring line portion.

The configurations of the first wiring line portions NL40 and the second wiring line portions WL41, WL42, and WL43 are substantially the same as those of the first wiring line portions NL1 and the second wiring line portions WLA, respectively, which are described with reference to FIGS. 1A and 1B. However, the surface roughness of a portion of the second wiring line portion WL41 that contacts the outermost insulating layer FLT4 may be greater than the surface roughness of each of the plurality of first wiring line portions NL40, where the second wiring line portion WL41 corresponds to a portion of the plurality of second wiring line portions WL41, WL42, and WL43. In addition, the second wiring line portions WL42 and WL43, which correspond to another portion of the plurality of second wiring line portions WL41, WL42, and WL43, may each include a first wide wiring line portion WLS, which is adjacent to the first wiring line portion NL40 in the horizontal direction, and a second wide wiring line portion WLR, which is integrally connected to the first wide wiring line portion WLS and spaced apart from the first wiring line portion NL40 in the horizontal direction with the first wide wiring line portion WLS therebetween. The surface roughness of a portion of the first wide wiring line portion WLS that contacts the outermost insulating layer FLT4 in each of the second wiring line portions WL42 and WL43 may be equal to or similar to the surface roughness of each of the plurality of first wiring line portions NL40. The surface roughness of a portion of the second wide wiring line portion WLR that contacts the outermost insulating layer FLT4 in each of the second wiring line portions WL42 and WL43 may be greater than the surface roughness of each of the plurality of first wiring line portions NL40. For example, the surface roughness of each of the plurality of first wiring line portions NL40 and the first wide wiring line portions WLS of the second wiring line portions WL42 and WL43 may be 0.1 μm or less, for example, about 0 μm to about 0.1 μm. The surface roughness of each of the second wiring line portion WL41 and the second wide wiring line portions WLR of the second wiring line portions WL42 and WL43 may have a value that is selected from a range of about 0.1 μm to about 0.6 μm and greater than the surface roughness of the first wide wiring line portion WLS.

The outermost insulating layer FLT4 may include a local insulating pattern 416 and an outer insulating pattern 418, which are in contact with each other. The local insulating pattern 416 may be on and/or cover the plurality of first wiring line portions NL40, which are included in the plurality of outermost wiring lines 412LT at the same vertical level, and the first wide wiring line portion WLS, which is adjacent to the first wiring line portion NL40, in each of the second wiring line portions WL42 and WL43. The local insulating pattern 416 may contact the plurality of first wiring line portions NL40 and the first wide wiring line portion WLS of each of the second wiring line portions WL42 and WL43. The outer insulating pattern 418 may be spaced apart from the plurality of first wiring line portions NL40 and the first wide wiring line portion WLS of each of the second wiring line portions WL42 and WL43 with the local insulating pattern 416 therebetween. The outer insulating pattern 418 may contact respective surfaces of portions of the plurality of second wiring line portions WL41, WL42, and WL43 and may not contact the first wide wiring line portion WLS. The surface roughness of portions of the plurality of first wiring line portions NL40 and the second wiring line portions WL42 and WL43 that contact the local insulating pattern 416 may be 0.1 μm or less, for example, about 0 μm to about 0.1 μm. The surface roughness of portions of the plurality of second wiring line portions WL41, WL42, and WL43 that contact the outer insulating pattern 418 may have a value that is selected from a range of about 0.1 μm to about 0.6 μm and greater than the surface roughness of the portions thereof contacting the local insulating pattern 416.

In the outermost insulating layer FLT4, the local insulating pattern 416 and the outer insulating pattern 418 may include different materials from each other. The configurations of the local insulating pattern 416 and the outer insulating pattern 418 are substantially the same as those of the local insulating pattern 116 and the outer insulating pattern 118, respectively, which are described with reference to FIGS. 1A and 1B.

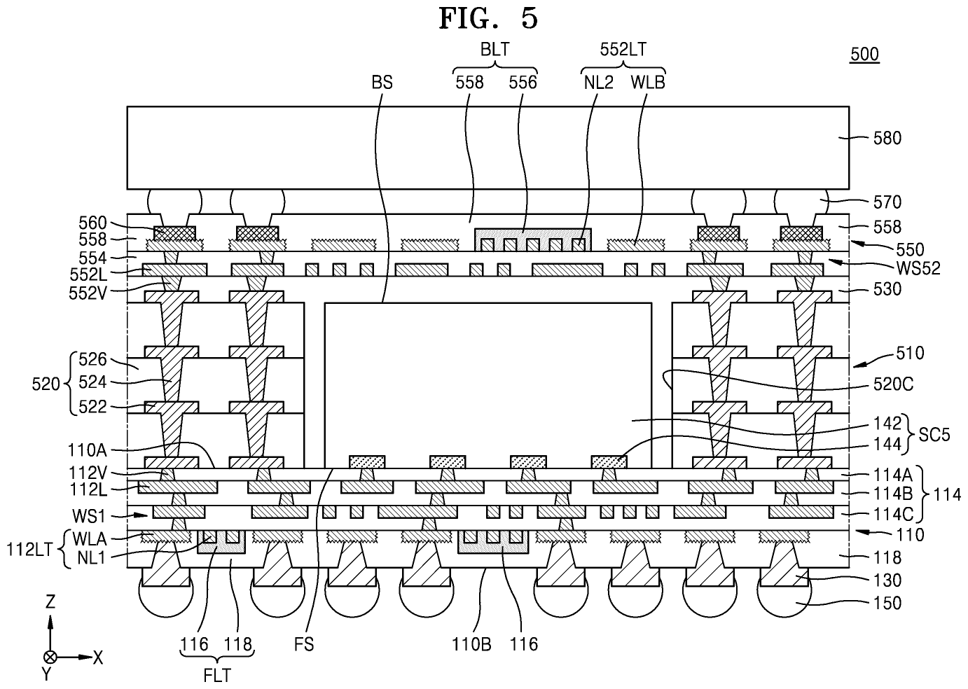

FIG. 5 is a cross-sectional view illustrating a semiconductor package 500 according to some embodiments. In FIG. 5, the same reference numerals shown in FIGS. 1A and 1B respectively denote the same members, and here, repeated descriptions thereof are omitted.

Referring to FIG. 5, the semiconductor package 500 may include a first package unit 510 arranged on the frontside redistribution structure 110. The first package unit 510 may have substantially the same configuration as the package unit 10 described with reference to FIGS. 1A and 1B. However, the first package unit 510 may correspond to a semiconductor package having a fan-out panel level package (FOPLP) structure. A backside redistribution structure 550 may be arranged on the first package unit 510, and a second package unit 580 may be arranged on the backside redistribution structure 550. The backside redistribution structure 550 may be on an inactive surface BS of a semiconductor chip SC5 in the vertical direction (Z direction).

The first package unit 510 may include a frame 520, the semiconductor chip SC5, and a molding layer 530. The semiconductor chip SC5 may have substantially the same configuration as the semiconductor chip SC described above with reference to FIG. 1A. In some embodiments, the semiconductor chip SC5 may include a CPU, a microprocessor unit (MPU), a graphics processor unit (GPU), or an AP. In some embodiments, the semiconductor chip SC5 may correspond to a controller semiconductor chip for controlling the second package unit 580.

In the first package unit 510, the frame 520 may include a plurality of connection pads 522, a plurality of conductive through-vias 524, and a plurality of cores 526. The frame 520 may include a printed circuit board. Each of the plurality of cores 526 may have a structure defining a cavity 520C and may include a plate having a quadrangular rim shape when viewed in a plane (the X-Y plane in FIG. 5).

The plurality of connection pads 522, the plurality of conductive through-vias 524, and the plurality of cores 526 may be arranged in a multilayered structure. Some of the plurality of connection pads 522 may be connected to the first wiring structure WS1 of the frontside redistribution structure 110. Each of the plurality of conductive through-vias 524 may extend through one of the plurality of cores 526 in the vertical direction (Z direction) and be connected to a connection pad 522.

In some embodiments, each of the plurality of cores 526 may include a thermosetting resin, such as a phenol resin or an epoxy resin, a thermoplastic resin, such as polyimide, or an insulating material in which at least one resin selected therefrom is impregnated into a core material including an inorganic filler and/or glass fiber. For example, each of the plurality of cores 526 may include, but is not limited to, prepreg, ABF, Flame Retardant 4 (FR-4), tetrafunctional epoxy, polyphenylene ether, BT, epoxy/polyphenylene oxide, Thermount, cyanate ester, polyimide, a liquid crystal polymer, or a combination thereof.

In some embodiments, each of the plurality of connection pads 522 may include, but is not limited to, electrolytically deposited (ED) copper foil, rolled-annealed (RA) copper foil, stainless steel foil, aluminum foil, ultra-thin copper foil, sputtered copper, or a copper alloy. In some embodiments, each of the plurality of conductive through-vias 524 may include, but is not limited to, copper, nickel, stainless steel, beryllium copper, or a combination thereof.

The molding layer 530 may include portions filling spaces between the plurality of cores 526 and the semiconductor chip SC5 in the cavity 520C, which is defined by the plurality of cores 526, and portions on and/or covering the upper surface of each of the frame 520 and the semiconductor chip SC5. The molding layer 530 may include an epoxy-based material, a thermosetting material, a thermoplastic material, or the like. For example, the molding layer 530 may include ABF, FR-4, BT, an EMC, or the like.

The backside redistribution structure 550 on the first package unit 510 may include a second wiring structure WS52. The second wiring structure WS52 may include a plurality of wiring lines 552LT and 552L, which are respectively arranged at a plurality of vertical levels having different vertical distances from each other from the first package unit 510, and a plurality of conductive via patterns 552V respectively connected to the plurality of wiring lines 552LT and 552L. The plurality of wiring lines 552LT and 552L may include a plurality of outermost wiring lines 552LT, which are arranged at the outermost vertical level having the greatest vertical distance from the first package unit 510 from among the plurality of vertical levels. Furthermore, the plurality of wiring lines 552LT and 552L may include a plurality of inner wiring lines 552L arranged between the first package unit 510 and the plurality of outermost wiring lines 552LT. The vertical distance between the first package unit 510 and each of the plurality of inner wiring lines 552L may be less than the vertical distance between the first package unit 510 and each of the plurality of outermost wiring lines 552LT.

The backside redistribution structure 550 may include a plurality of insulating layers BLT and 554 respectively on and/or covering the plurality of wiring lines 552LT and 552L. The plurality of insulating layers BLT and 554 may include an outermost insulating layer BLT, which is on and/or covers the plurality of outermost wiring lines 552LT, and an inner insulating layer 554, which is on and/or covers the plurality of inner wiring lines 552L. The inner insulating layer 554 may cover the plurality of inner wiring lines 552L arranged at one vertical level between the first package unit 510 and the outermost insulating layer BLT. The inner insulating layer 554 may include a single layer.

The plurality of outermost wiring lines 552LT may each have a different surface roughness from each other that is based on the respective widths of the plurality of outermost wiring lines 552LT in the horizontal direction (for example, the X direction in FIG. 5). The plurality of outermost wiring lines 552LT may include a plurality of first wiring line portions NL2, which have relatively small widths in the horizontal direction (for example, the X direction in FIG. 5), and a plurality of second wiring line portions WLB, which have relatively larger/greater widths in the horizontal direction. In the plurality of outermost wiring lines 552LT, the surface roughness of at least a portion of each of the plurality of second wiring line portions WLB may be greater than the surface roughness of each of the plurality of first wiring line portions NL2. The detailed configurations of the plurality of first wiring line portions NL2 and the plurality of second wiring line portions WLB, which are included in the plurality of outermost wiring lines 552LT, are substantially the same as those of the plurality of first wiring line portions NL1 and the plurality of second wiring line portions WLA, respectively, which are described with reference to FIGS. 1A and 1B. Herein, each of the plurality of first wiring line portions NL2 in the plurality of outermost wiring lines 552LT may be referred to as a narrow wiring line portion, and each of the plurality of second wiring line portions WLB in the plurality of outermost wiring lines 552LT may be referred to as a wide wiring line portion.

In some embodiments, in the plurality of outermost wiring lines 552LT, the minimum width of each of the plurality of first wiring line portions NL2 in the horizontal direction may be 10 μm or less and, for example, may be selected from a range of about 5 μm to about 10 μm. The minimum width of each of the plurality of second wiring line portions WLB in the horizontal direction may be greater than 10 μm. In some embodiments, the surface roughness of the surface of each of the plurality of first wiring line portions NL2 that contact the outermost insulating layer BLT may be 0.1 μm or less, for example, about 0 μm to about 0.1 μm, and the surface roughness of the surface of each of the plurality of second wiring line portions WLB that contact the outermost insulating layer BLT. may have a value that is selected from a range of about 0.1 μm to about 0.6 μm and greater than the surface roughness of each of the plurality of first wiring line portions NL2. In some embodiments, the surface roughness of each of the plurality of inner wiring lines 552L may be 0.1 μm or less and is independent of the respective widths of the plurality of inner wiring lines 552L in the horizontal direction.

The outermost insulating layer BLT may include a local insulating pattern 556, which is on and/or covers the plurality of first wiring line portions NL2 of the plurality of outermost wiring lines 552LT that are at the same vertical level. The outermost insulating layer BLT may include an outer insulating pattern 558, which is spaced apart from the plurality of first wiring line portions NL2 with the local insulating pattern 556 therebetween. The local insulating pattern 556 may contact the surface of each of the plurality of first wiring line portions NL2 but may not contact the surface of each of the plurality of second wiring line portions WLB. The outer insulating pattern 558 may contact each of the local insulating pattern 556 and the plurality of second wiring line portions WLB. The detailed configurations of the inner insulating layer 554, the local insulating pattern 556, and the outer insulating pattern 558 are substantially the same as those of the inner insulating layer 114, the local insulating pattern 116, and the outer insulating pattern 118, respectively, which are described with reference to FIGS. 1A and 1B.

As shown in FIG. 5, the second wiring structure WS52 of the backside redistribution structure 550 may be connected to the plurality of connection pads 522 and the plurality of conductive through-vias 524, which are included in the frame 520 of the first package unit 510.

A plurality of connection pads 560 may be respectively arranged on some outermost wiring lines 552LT selected from the plurality of outermost wiring lines 552LT of the backside redistribution structure 550. Each of the plurality of connection pads 560 may contact a surface of an outermost wiring line 552LT. The surface roughness of the surface of the outermost wiring line 552LT, which is in contact with the connection pad 560, may be about 0.1 μm to about 0.6 μm. Each of the plurality of connection pads 560 may include, but is not limited to, Ni, Au, or a combination thereof.

A plurality of connection terminals 570 may be arranged between the plurality of connection pads 560 and the second package unit 580. Each of the plurality of connection terminals 570 may be connected to one outermost wiring line 552LT selected from the plurality of outermost wiring lines 552LT via the connection pad 560. Each of the plurality of connection pads 560 may not contact the plurality of first wiring line portions NL2 of the second wiring structure WS52.

The second package unit 580 may be electrically connected to the semiconductor chip SC5 and/or each external connection terminal 150 via an electrical path including various combinations of the connection terminal 570, the connection pad 560, the second wiring structure WS52 of the backside redistribution structure 550, the plurality of connection pads 522, the plurality of conductive through-vias 524, the frontside redistribution structure 110, and the conductive pad 130.

The second package unit 580 may be flip-chip-bonded onto the first package unit 510. In some embodiments, the semiconductor chip SC5 in the first package unit 510 and a semiconductor chip in the second package unit 580 may correspond to devices performing different functions. For example, the semiconductor chip SC5 may include a logic chip and the semiconductor chip in the second package unit 580 may include a memory chip. The logic chip may include a microprocessor. For example, the logic chip may include a CPU, a controller, an ASIC, or the like. The memory chip may include a volatile memory chip, such as DRAM or SRAM, or a non-volatile memory chip, such as PRAM, MRAM, FeRAM, or RRAM. In some embodiments, the memory chip may include an HBM DRAM semiconductor chip.

In some embodiments, the semiconductor chip SC5 in the first package unit 510 and the semiconductor chip in the second package unit 580 may correspond to devices performing the same or similar functions. For example, at least one of the semiconductor chip SC5 in the first package unit 510 and the semiconductor chip in the second package unit 580 may include an SoC type AP chip used in a mobile system, for example, a mobile phone, an MP3 player, a navigation system, a PMP, or the like, or may include a DDR chip used in a mobile system.

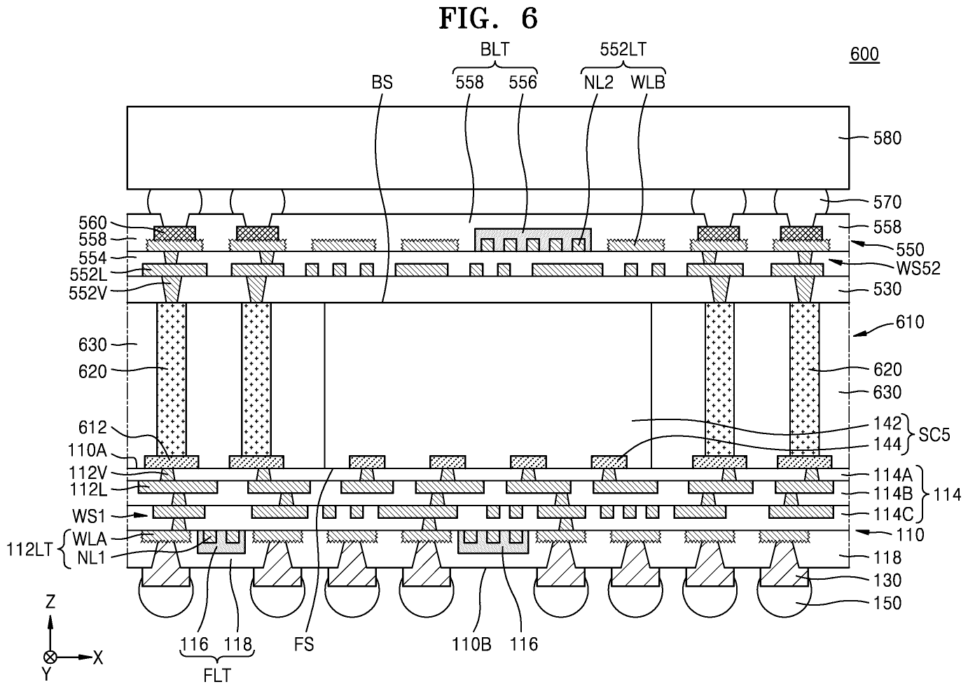

FIG. 6 is a cross-sectional view illustrating a semiconductor package 600 according to some embodiments. In FIG. 6, the same reference numerals shown in FIGS. 1A, 1, and 5 respectively denote the same members, and here, repeated descriptions thereof are omitted.

Referring to FIG. 6, the semiconductor package 600 may include a first package unit 610 arranged on the frontside redistribution structure 110. The first package unit 610 may have substantially the same configuration as the package unit 10 described above with reference to FIGS. 1A and 1B. However, the first package unit 610 may correspond to a semiconductor package having a fan-out wafer level package (FOWLP) structure. The first package unit 610 may have substantially the same configuration as the first package unit 510 described with reference to FIG. 5. However, the first package unit 610 may include a plurality of conductive posts 620 arranged on the first surface 110A of the frontside redistribution structure 110 and around the semiconductor chip SC5. Each of the plurality of conductive posts 620 may be connected to the first wiring structure WS1 of the frontside redistribution structure 110 via one wiring pattern 612 selected from a plurality of wiring patterns 612, which are arranged on the first surface 110A of the frontside redistribution structure 110. Each of the plurality of conductive posts 620 may be connected to at least some of the plurality of outermost wiring lines 112LT, the plurality of inner wiring lines 112L, and the plurality of conductive via patterns 112V, which are included in the first wiring structure WS1 of the frontside redistribution structure 110. Each of the plurality of conductive posts 620 may include, but is not limited to, copper (Cu).

Spaces between the semiconductor chip SC5 and each of the plurality of conductive posts 620 may be filled with a molding layer 630. In some embodiments, the molding layer 630 may include an epoxy-based material, a thermosetting material, a thermoplastic material, or the like. For example, the molding layer 630 may include an EMC. In some embodiments, the molding layer 630 may include ABF, FR-4, BT, an EMC, or the like.

The backside redistribution structure 550 may be arranged on the first package unit 610, and the second package unit 580 may be arranged on the backside redistribution structure 550. Detailed configurations of the backside redistribution structure 550 and the second package unit 580 are the same as described above with reference to FIG. 5.

In the semiconductor package 600, some conductive pads 130 from among the plurality of conductive pads 130 may be connected to the semiconductor chip SC5 via the first wiring structure WS1 of the frontside redistribution structure 110, and some other conductive pads 130 from among the plurality of conductive pads 130 may be connected to the conductive posts 620 via the first wiring structure WS1 of the frontside redistribution structure 110.

Although FIGS. 5 and 6 illustrate an example in which each of the semiconductor packages 500 and 600 includes the frontside redistribution structure 110 having the structure described with reference to FIGS. 1A and 1B between the semiconductor chip SC5 and the plurality of external connection terminals 150, the present disclosure is not limited to the example shown in FIGS. 5 and 6. In some embodiments, each of the semiconductor packages 500 and 600 may include the frontside redistribution structure 210, 310, or 410 described with reference to FIGS. 2 to 4 or a frontside redistribution structure having a structure variously modified and changed therefrom without departing from the spirit and scope of the present disclosure

According to the semiconductor packages 200, 300, 400, 500, and 600 described with reference to FIGS. 2 to 6, and similar to the semiconductor package 100 described with reference to FIGS. 1A and 1B, the plurality of outermost wiring lines 112LT, 212LT, 312LT, or 412LT of the frontside redistribution structure 110, 210, 310, or 410 may include the plurality of first wiring line portions NL1, NL20, NL30, or NL40, which have relatively small widths and relatively small surface roughness, and the plurality of second wiring line portions WLA, WL21, WL22, WL23, WL24, WL31, WL32, WL41, WL42, or WL43, which have relatively larger/greater widths and relatively great surface roughness. Therefore, the adhesion between the plurality of second wiring line portions WLA, WL21, WL22, WL23, WL24, WL31, WL32, WL41, WL42, or WL43 and the outer insulating pattern 118, 318, or 418 may improve, and the plurality of first wiring line portions NL1, NL20, NL30, or NL40 may be covered and protected by the local insulating pattern 116, 216, 316, or 416. Therefore, the plurality of first wiring line portions NL1, NL20, NL30, or NL40 having relatively small widths may be inhibited from various defects, such as collapse or lifting, due to a reduction in the linewidths thereof, and the adhesion between the plurality of first wiring line portions NL1, NL20, NL30, or NL40 and the local insulating pattern 116, 216, 316, or 416 may be secured.

In addition, the plurality of outermost wiring lines 552LT of the backside redistribution structure 550 may include the plurality of first wiring line portions NL2, which have relatively small widths and relatively small surface roughness, and the plurality of second wiring line portions WLB have relatively larger/greater widths and a relatively greater/larger surface roughness. Therefore, the adhesion between the plurality of second wiring line portions WLB and the outer insulating pattern 558 may improve, and the plurality of first wiring line portions NL2 may be covered and protected by the local insulating pattern 556. Furthermore, the plurality of first wiring line portions NL2 having relatively small widths may be inhibited from defects, such as collapse or lifting, due to a reduction in the linewidths thereof, and the adhesion between the plurality of first wiring line portions NL2 and the local insulating pattern 556 may be secured.

Therefore, even when the plurality of outermost wiring lines, which are included in each of the frontside redistribution structures 110, 210, 310, and 410 and the backside redistribution structure 550, have various linewidths and the minimum linewidth in the plurality of outermost wiring lines is reduced, the minimum dimension for the plurality of outermost wiring lines may be secured. In addition, the adhesion between each of the plurality of outermost wiring lines and the outermost insulating layer covering each thereof may be secured, thereby improving the reliability and manufacturing process efficiency of each of the semiconductor packages 200, 300, 400, 500, and 600.

Next, a method of manufacturing a semiconductor package, according to some embodiments of the present disclosure is described in detail.

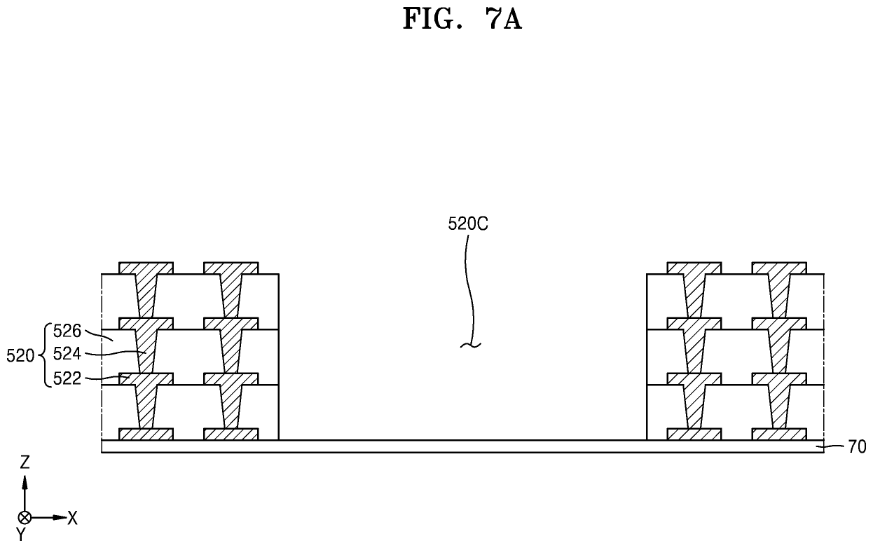

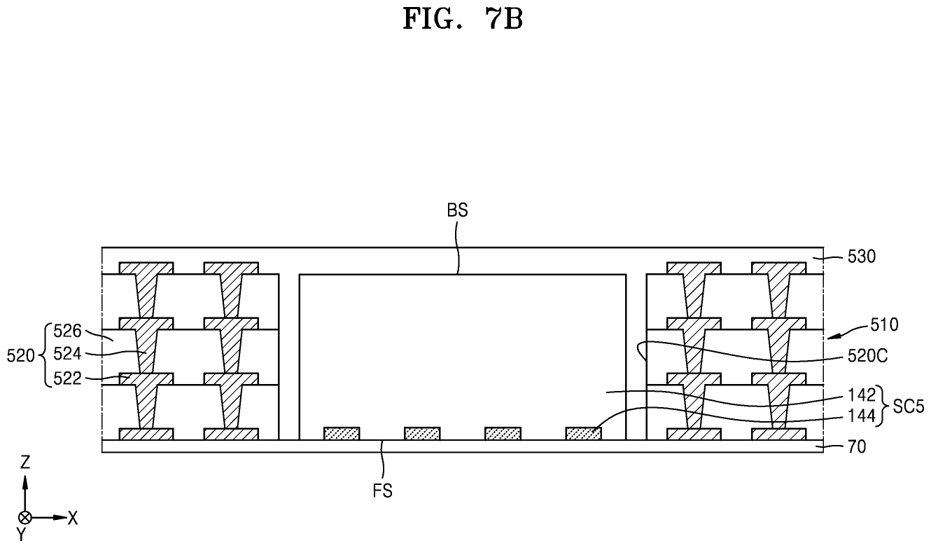

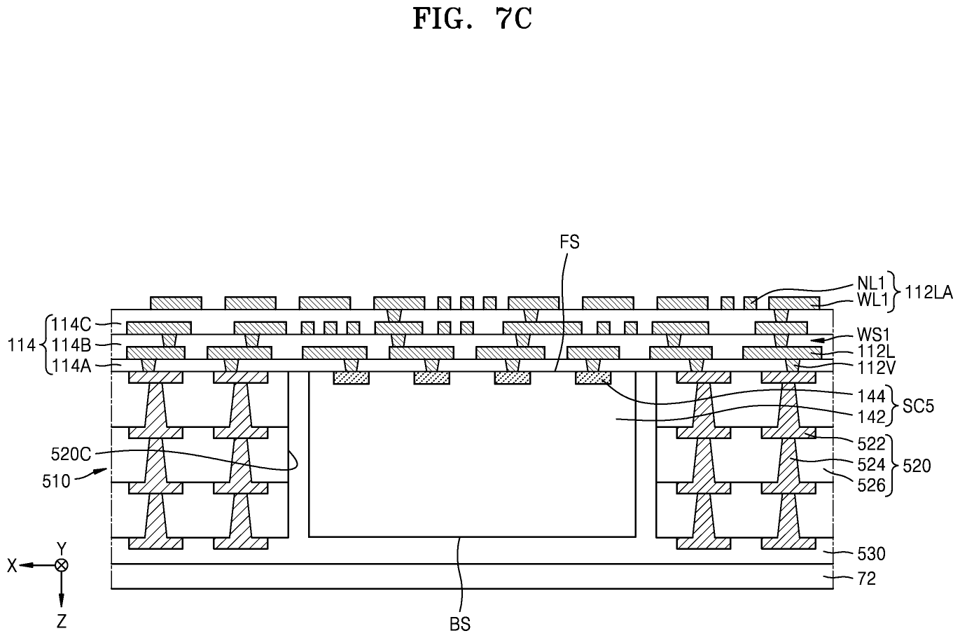

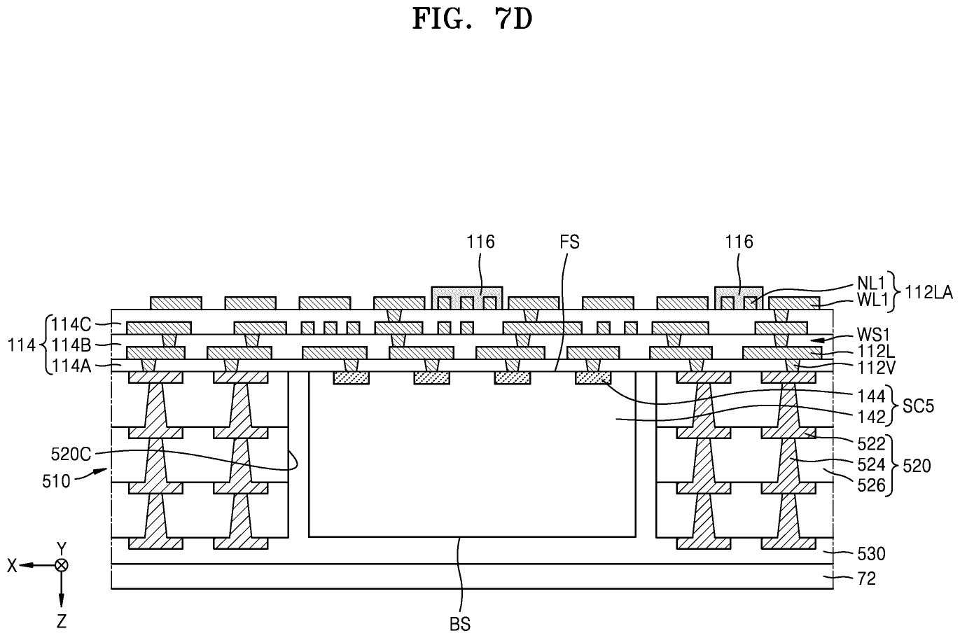

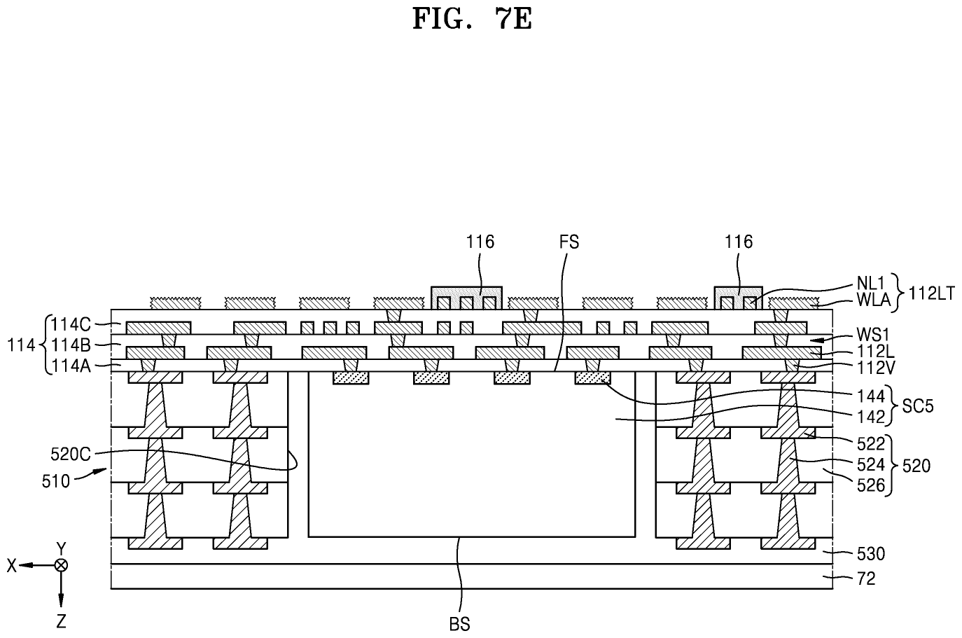

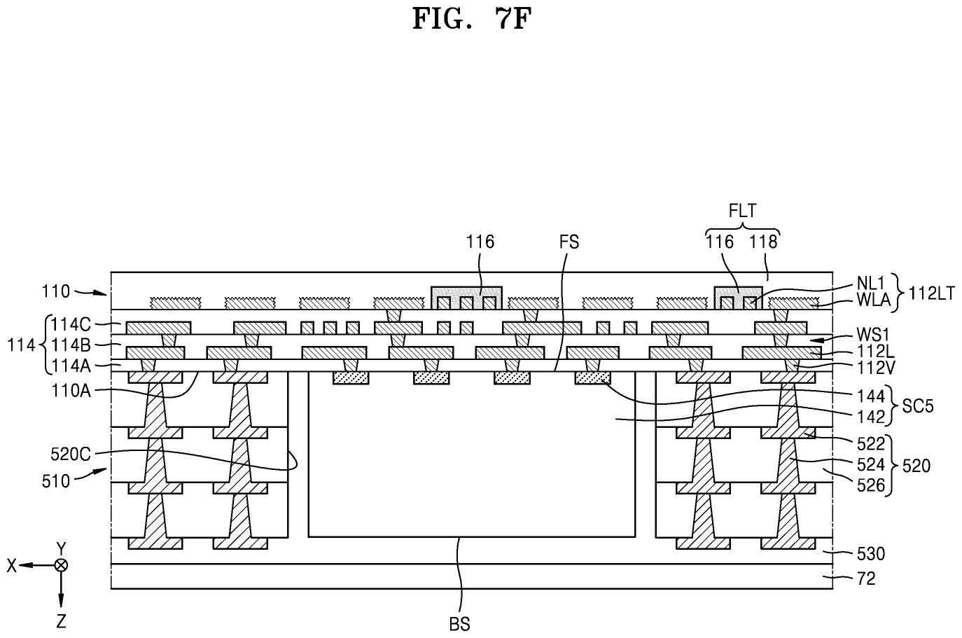

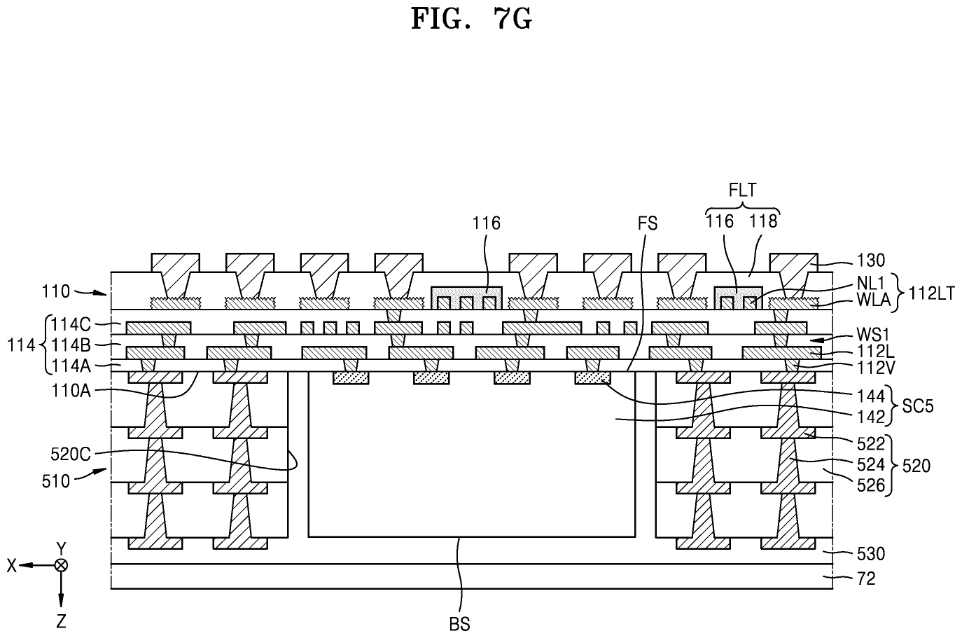

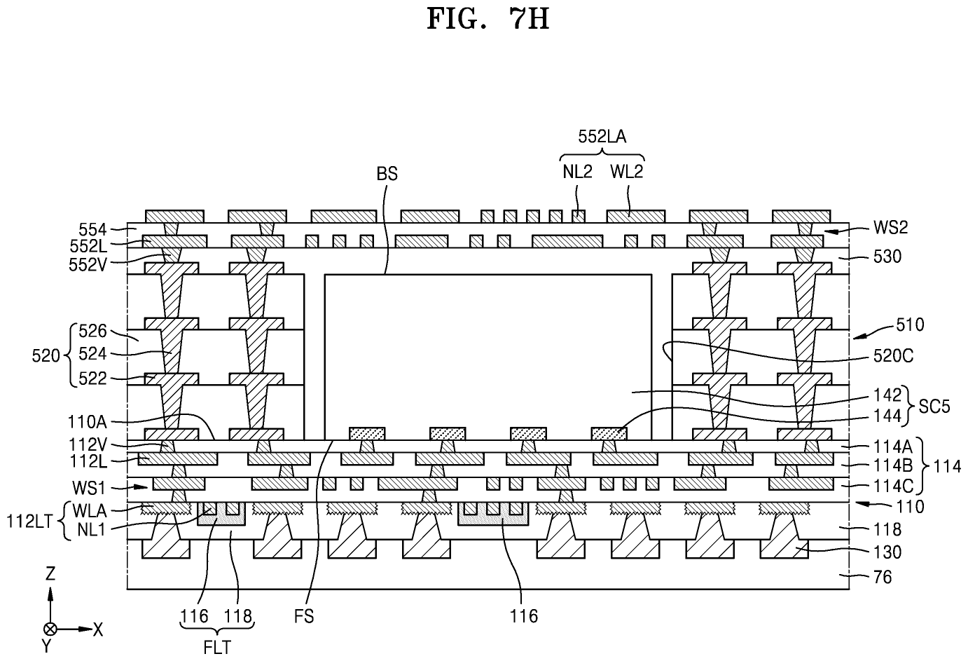

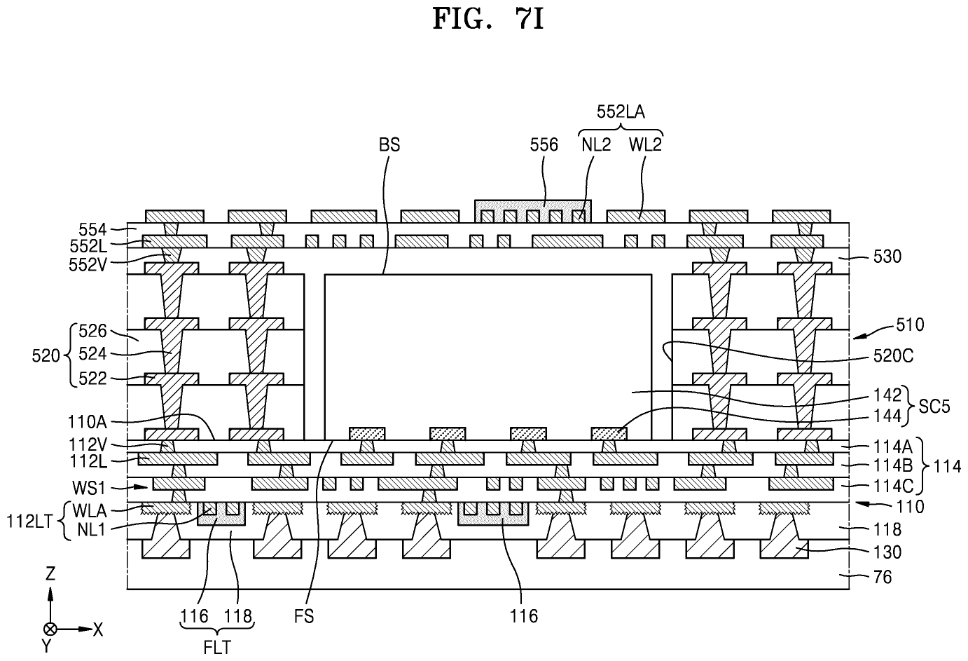

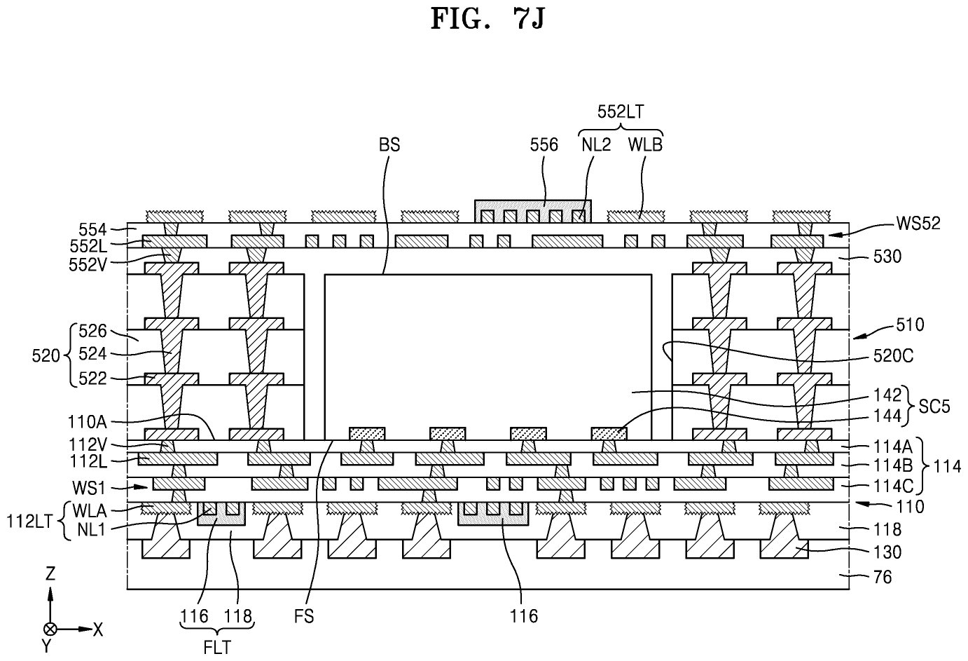

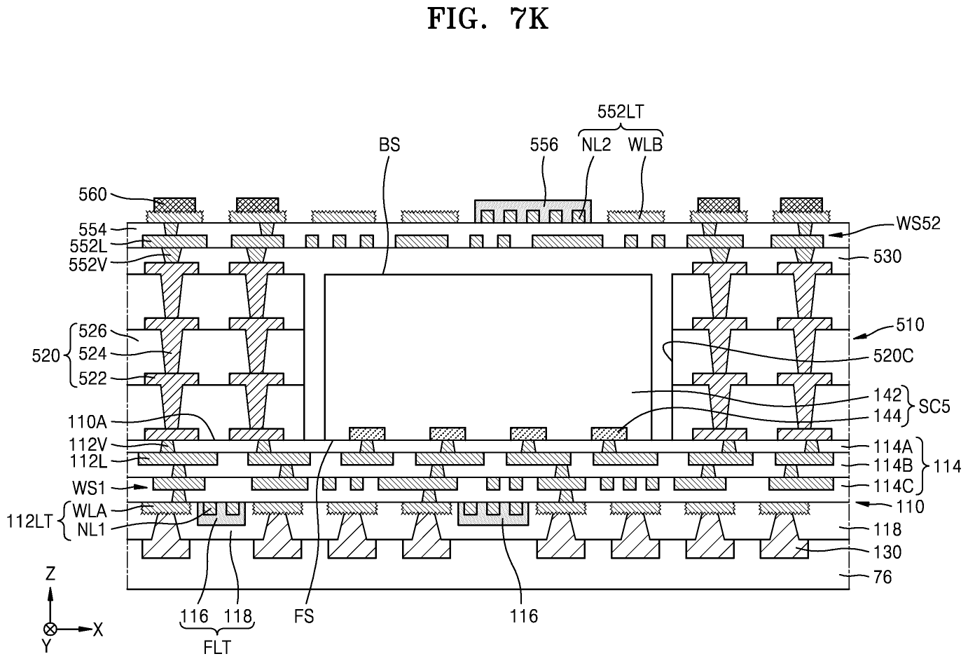

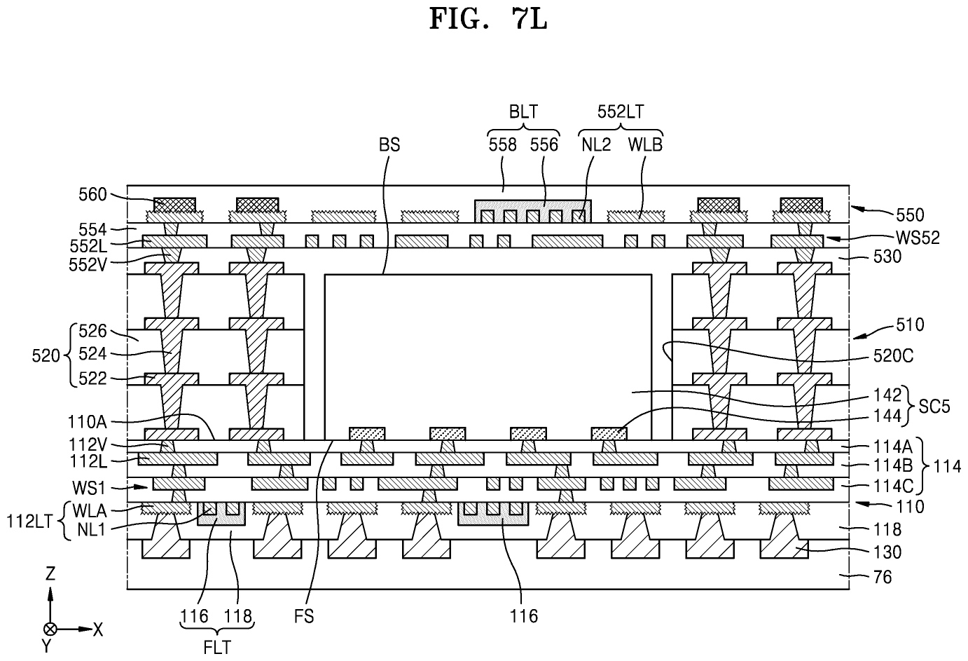

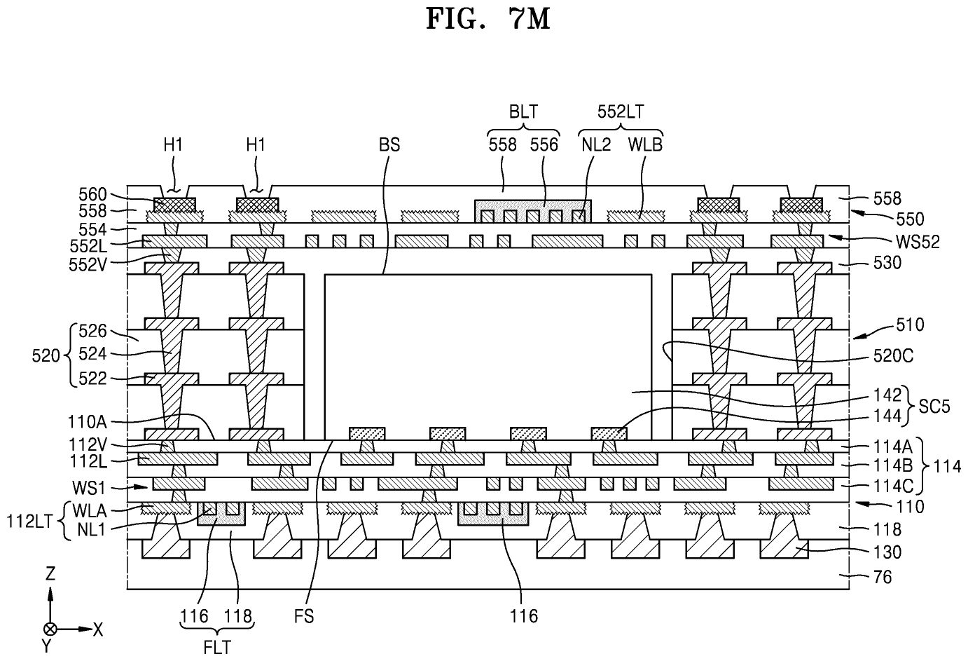

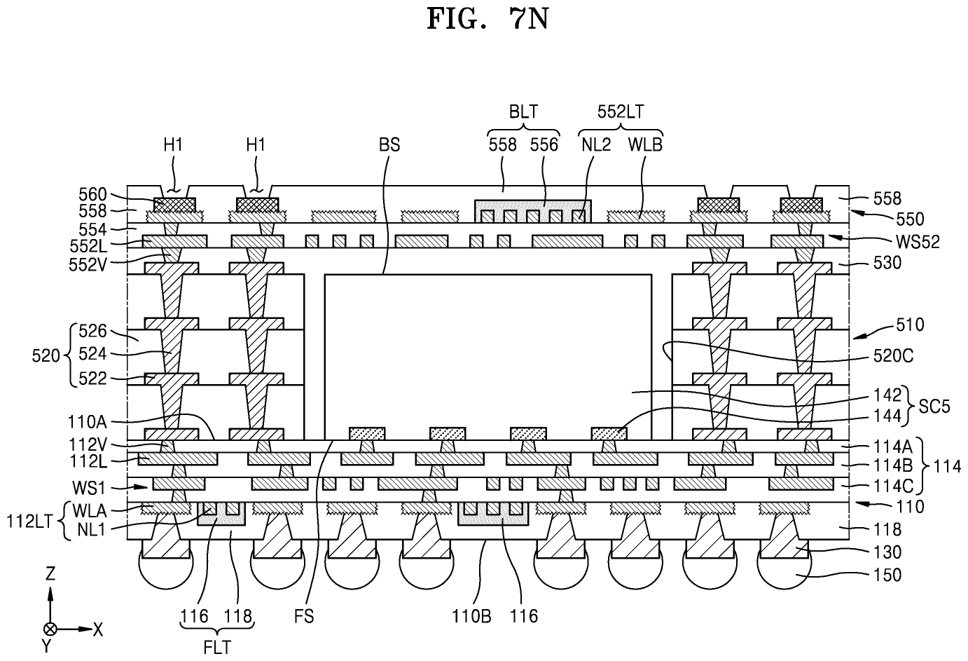

FIGS. 7A to 7N are cross-sectional views respectively illustrating a sequence of processes of a method of manufacturing a semiconductor package according to some embodiments of the present disclosure. An example of a method of manufacturing the semiconductor package 500 shown in FIG. 5 is described with reference to FIGS. 7A to 7N. In FIGS. 7A to 7N, the same reference numerals shown in FIGS. 1A, 1, and 5 respectively denote the same members, and here, repeated descriptions thereof are omitted.

Referring to FIG. 7A, the cavity 520C may be formed through the frame 520, and then, the frame 520 may be attached onto a support film 70. In some embodiments, the support film 70 may include ABF.

Referring to FIG. 7B, in the resulting product of FIG. 7A, the semiconductor chip SC5 may be attached within the cavity 520C, and then the molding layer 530 may be formed to thereby form the first package unit 510.

The semiconductor chip SC5 may be arranged in the cavity 520C such that the active surface FS thereof, on which the plurality of chip pads 144 are formed, faces the support film 70. The semiconductor chip SC5 may be spaced apart from an inner sidewall of the cavity 520C in the horizontal direction (for example, the X direction and the Y direction in FIG. 7B).

The molding layer 530 may be formed to fill a space between the semiconductor chip SC5 and the inner sidewall of the cavity 520C and cover the upper surface of each of the frame 520 and the semiconductor chip SC5. The molding layer 530 may secure the semiconductor chip SC5.

Referring to FIG. 7C, in the resulting product of FIG. 7B, a first carrier substrate 72 may be attached onto the molding layer 530, and the support film 70 may be removed. The first carrier substrate 72 may include a glass substrate, a silicon substrate, a metal substrate, or a combination thereof.

Next, a structure, which includes the plurality of inner wiring lines 112L, the plurality of conductive via patterns 112V, and the plurality of inner insulating layers 114 on and/or covering the plurality of inner wiring lines 112L and the plurality of conductive via patterns 112V, may be formed on a surface of the first package unit 510, at which the active surface FS of the semiconductor chip SC5 is exposed. Next, a plurality of outermost preliminary wiring lines 112LA may be formed on the third inner insulating layer 114C of the plurality of inner insulating layers 114. The plurality of outermost preliminary wiring lines 112LA may include a plurality of first wiring line portions NL1 and a plurality of preliminary second wiring line portions WL1, where each of the plurality of first wiring line portions NL1 have a different width in the horizontal direction from each of the plurality of preliminary second wiring line portions WL1. The width of each of the plurality of preliminary second wiring line portions WL1 may be greater in the horizontal direction than the width of each of the plurality of first wiring line portions NL1. For example, the width of each of the plurality of first wiring line portions NL1 may be 10 μm or less, for example, about 5 μm to about 10 μm, and the width of each of the plurality of preliminary second wiring line portions WL1 may be greater than 10 μm. In some embodiments, the surface roughness of each of the plurality of first wiring line portions NL1 and the plurality of preliminary second wiring line portions WL1 may be 0.1 μm or less.

In some embodiments, the plurality of inner wiring lines 112L, the plurality of conductive via patterns 112V, the plurality of first wiring line portions NL1, and the plurality of preliminary second wiring line portions WL1 may each be formed by a plating process. The plating process may include an electroplating process, an electroless plating process, or an electrolytic plating process.

Referring to FIG. 7D, the local insulating pattern 116 may be formed to selectively cover the plurality of first wiring line portions NL1 of the plurality of outermost preliminary wiring lines 112LA.

In some embodiments, to form the local insulating pattern 116, a preliminary insulating layer may be formed to cover the entire surface of the resulting product of FIG. 7C, at which the plurality of outermost preliminary wiring lines 112LA and the third inner insulating layer 114C are exposed, followed by patterning the preliminary insulating layer by a photolithography process, thereby leaving the local insulating pattern 116 obtained from a portion of the preliminary insulating layer.

In some embodiments, to form the local insulating pattern 116, an inkjet coating process may be used. To this end, an insulating material may be coated on the resulting product of FIG. 7C by an inkjet coating process to selectively cover the plurality of first wiring line portions NL1 of the plurality of outermost preliminary wiring lines 112LA and some regions of the third inner insulating layer 114C around the plurality of first wiring line portions NL1, followed by curing the coated insulating material to thereby form the local insulating pattern 116.

Referring to FIG. 7E, while the plurality of first wiring line portions NL1 are covered by the local insulating pattern 116 and the plurality of preliminary second wiring line portions WL1 are exposed, the surface roughness of each of the plurality of preliminary second wiring line portions WL1 may be increased to thereby form the plurality of second wiring line portions WLA having a relatively greater/larger surface roughness. In some embodiments, the surface roughness of each of the plurality of second wiring line portions WLA may be about 0.1 μm to about 0.6 μm. The plurality of first wiring line portions NL1 and the plurality of second wiring line portions WLA may constitute the plurality of outermost wiring lines 112LT.

To increase the surface roughness of each of the plurality of preliminary second wiring line portions WL1, a chemical method, a physical method, or a combination thereof may be used.

In some embodiments, to increase the surface roughness of each of the plurality of preliminary second wiring line portions WL1 by a chemical method, a treatment process using a soft-etching solution including hydrogen peroxide (H₂O₂), sulfuric acid (H₂SO₄), and a stabilizer, a treatment process using a Chemical Zet (CZ, MAC Co., Ltd.) solution including formic acid and CuCl₂, a black oxide formation process, a brown oxide formation process, an acid base chemical (ABC) treatment process, or a combination thereof may be used, but the present disclosure is not limited thereto.

In some embodiments, to increase the surface roughness of each of the plurality of preliminary second wiring line portions WL1 by a physical method, a sand blast treatment process, a ceramic buff treatment process, a Z-scrubbing treatment process, or a combination thereof may be used, but the present disclosure is not limited thereto.

Referring to FIG. 7F, in the resulting product of FIG. 7E, the outer insulating pattern 118 may be formed to cover the local insulating pattern 116 and the plurality of second wiring line portions WLA, thereby forming the frontside redistribution structure 110.

The outer insulating pattern 118 may include a different material from the constituent material of the local insulating pattern 116. A specific constituent material of each of the local insulating pattern 116 and the outer insulating pattern 118 is the same as described with reference to FIGS. 1A and 1B.

The outer insulating pattern 118 may be formed to contact each of the local insulating patterns 116 and the plurality of second wiring line portions WLA. Because the plurality of second wiring line portions WLA have relatively greater/larger surface roughness, the adhesion between the plurality of second wiring line portions WLA and the outer insulating pattern 118 may improve. The local insulating pattern 116 and the outer insulating pattern 118 may constitute the outermost insulating layer FLT.

Referring to FIG. 7G, portions of the outer insulating pattern 118 may be removed from the resulting product of FIG. 7F, thereby exposing a plurality of contact surfaces, which correspond to portions of the plurality of second wiring line portions WLA. In some embodiments, a process of removing the portions of the outer insulating pattern 118 to expose the plurality of contact surfaces of the plurality of second wiring line portions WLA may be performed by using a laser, but the present disclosure is not limited thereto.

Next, the plurality of conductive pads 130 may be formed through the outer insulating pattern 118 to respectively contact the plurality of contact surfaces.

Referring to FIG. 7H, a second carrier substrate 76 may be attached to the resulting product of FIG. 7G to cover exposed surfaces of the plurality of conductive pads 130 and the frontside redistribution structure 110, and the molding layer 530 may be exposed by removing the first carrier substrate 72 (see FIG. 7G). The second carrier substrate 76 may include a glass substrate, a silicon substrate, a metal substrate, or a combination thereof.

Next, the plurality of conductive via patterns 552V, the plurality of inner wiring lines 552L, and the inner insulating layer 554, which covers the plurality of conductive via patterns 552V and the plurality of inner wiring lines 552L, may be formed on the molding layer 530.

Next, a plurality of outermost preliminary wiring lines 552LA may be formed on the inner insulating layer 554. The plurality of outermost preliminary wiring lines 552LA may include the plurality of first wiring line portions NL2 and a plurality of preliminary second wiring line portions WL2, each of the plurality of first wiring line portions NL2 having a different width in the horizontal direction from each of the plurality of preliminary second wiring line portions WL2. The width of each of the plurality of preliminary second wiring line portions WL2 may be greater in the horizontal direction than the width of each of the plurality of first wiring line portions NL2. For example, the width of each of the plurality of first wiring line portions NL2 may be 10 μm or less, for example, about 5 μm to about 10 μm, and the width of each of the plurality of preliminary second wiring line portions WL2 may be greater than 10 μm. In some embodiments, the surface roughness of each of the plurality of first wiring line portions NL2 and the plurality of preliminary second wiring line portions WL2 may be 0.1 μm or less.

In some embodiments, the plurality of inner wiring lines 552L, the plurality of conductive via patterns 552V, the plurality of first wiring line portions NL2, and the plurality of preliminary second wiring line portions WL2 may each be formed by a plating process. Regarding specific examples of the plating process, a reference may be made to the description made with reference to FIG. 7C.

Referring to FIG. 7I, and in a similar manner to the description made with reference to FIG. 7D regarding the formation of the local insulating pattern 116, the local insulating pattern 556 may be formed to selectively cover the plurality of first wiring line portions NL2 of the plurality of outermost preliminary wiring lines 552LA.

Referring to FIG. 7J, and in a similar manner to the description made with reference to FIG. 7E, while the plurality of first wiring line portions NL2 are covered by the local insulating pattern 556 and the plurality of preliminary second wiring line portions WL2 are exposed, the surface roughness of each of the plurality of preliminary second wiring line portions WL2 may be increased, thereby forming the plurality of second wiring line portions WLB having a relatively greater/larger surface roughness. In some embodiments, the surface roughness of each of the plurality of second wiring line portions WLB may be about 0.1 μm to about 0.6 μm. The plurality of first wiring line portions NL2 and the plurality of second wiring line portions WLB may constitute the plurality of outermost wiring lines 552LT.

Regarding a specific method of increasing the surface roughness of each of the plurality of preliminary second wiring line portions WL2, a reference may be made to the description made with reference to FIG. 7E regarding the method of increasing the surface roughness of each of the plurality of preliminary second wiring line portions WL1.

Referring to FIG. 7K, the plurality of connection pads 560 may be formed to cover a plurality of contact surfaces, which correspond to portions selected from the plurality of second wiring line portions WLB. The plurality of connection pads 560 may contact the plurality of contact surfaces of the plurality of second wiring line portions WLB. Because the plurality of contact surfaces of the plurality of second wiring line portions WLB may each have a relatively greater/larger surface roughness selected from a range of about 0.1 μm to about 0.6 μm, the adhesion between the plurality of connection pads 560 and the plurality of contact surfaces of the plurality of second wiring line portions WLB may improve.

In some embodiments, to form the plurality of connection pads 560, a photoresist film (not shown) may be formed on the resulting product of FIG. 7J to cover respective exposed surfaces of the plurality of outermost wiring lines 552LT and the inner insulating layer 554, followed by performing light-exposure and development processes on the photoresist film, thereby forming a plurality of contact holes to expose the plurality of contact surfaces of the plurality of second wiring line portions WLB. Next, the plurality of connection pads 560 may be respectively formed on the plurality of contact surfaces exposed in the plurality of contact holes, and then, the photoresist pattern may be removed.

Referring to FIG. 7L, the outer insulating pattern 558 may be formed on the resulting product of FIG. 7K to cover the local insulating pattern 556 and the plurality of second wiring line portions WLB, thereby forming the backside redistribution structure 550 including the outermost insulating layer BLT.

Referring to FIG. 7M, in the resulting product of FIG. 7L, portions of the outer insulating pattern 558 may be etched by using a laser, thereby forming a plurality of holes H1 to respectively expose the plurality of connection pads 560.

Referring to FIG. 7N, the plurality of conductive pads 130 may be exposed by removing the second carrier substrate 76 from the resulting product of FIG. 7M, and the plurality of external connection terminals 150 may be respectively formed on the plurality of conductive pads 130.

Next, the plurality of connection terminals 570 may be formed to be respectively connected to the plurality of connection pads 560 exposed by the plurality of holes H1, and the second package unit 580 may be attached onto the plurality of connection terminals 570, thereby forming the semiconductor package 500.

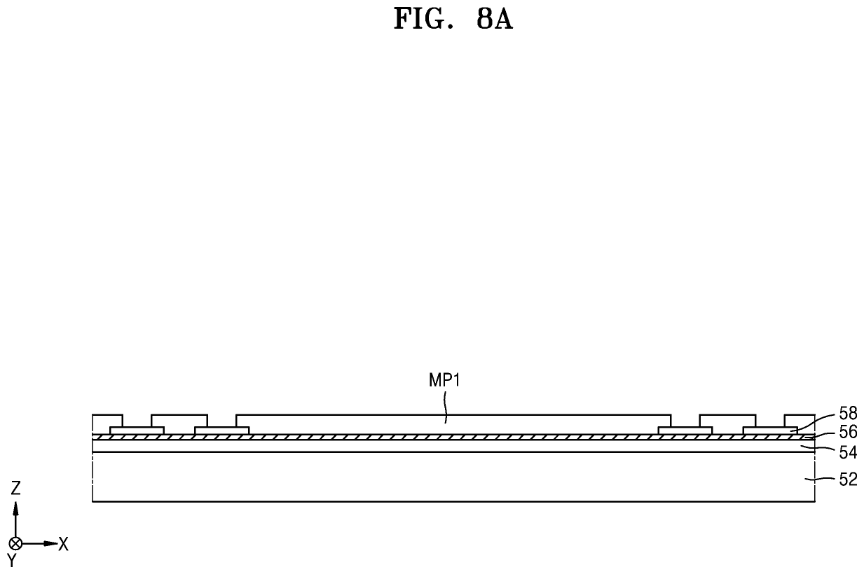

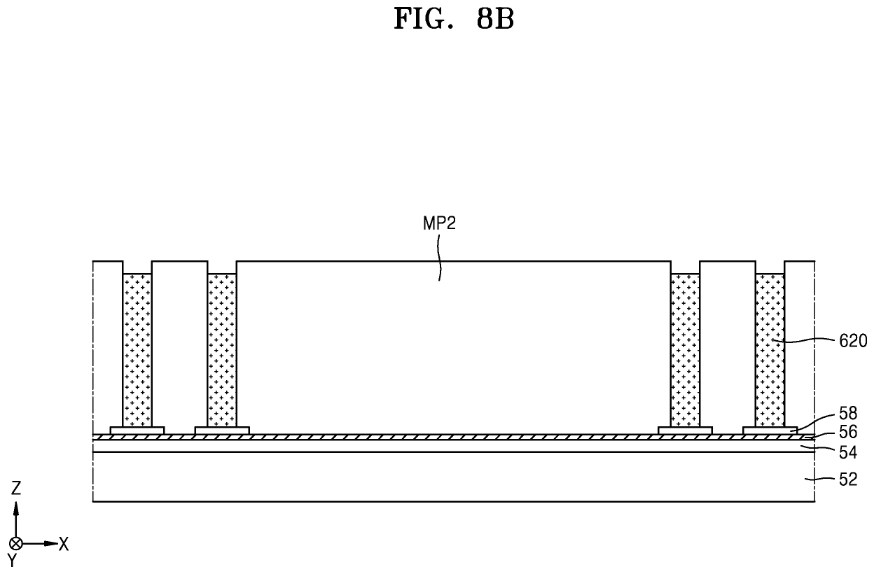

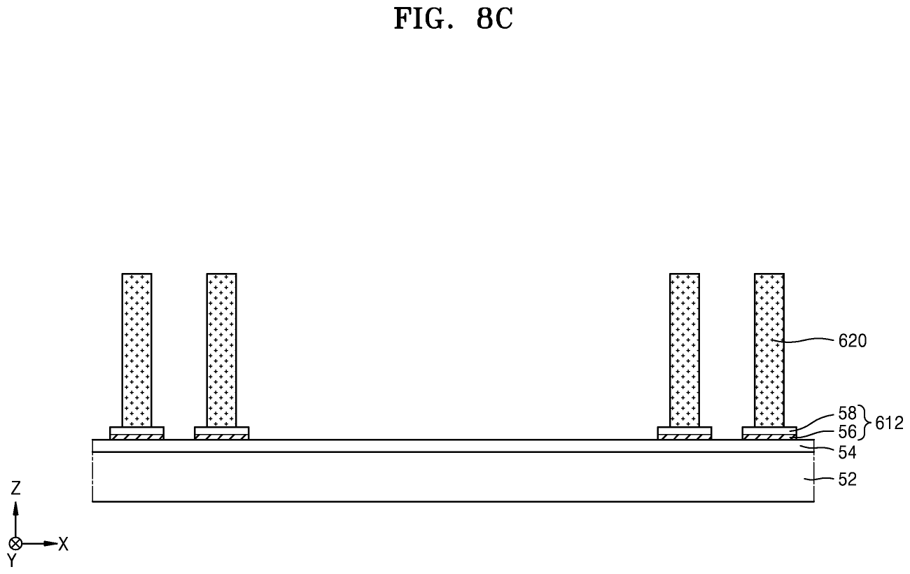

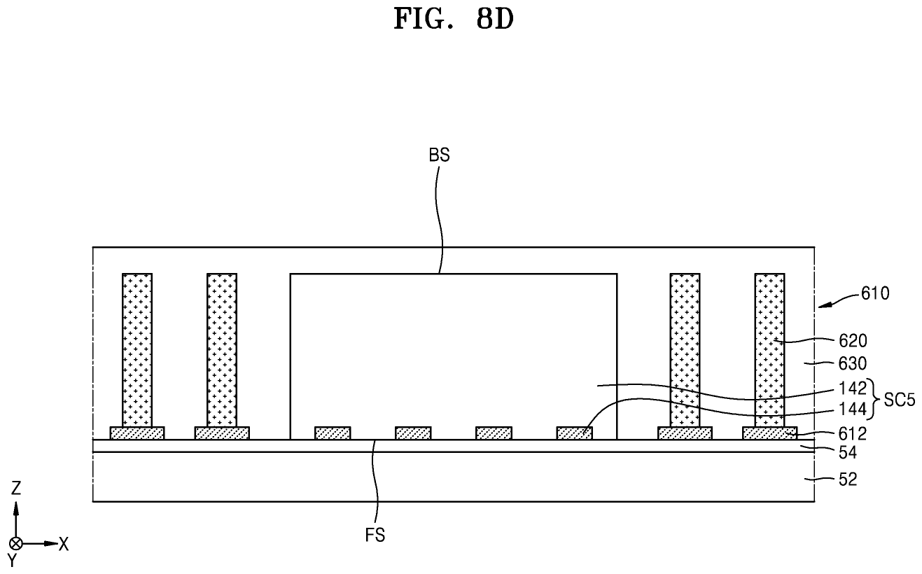

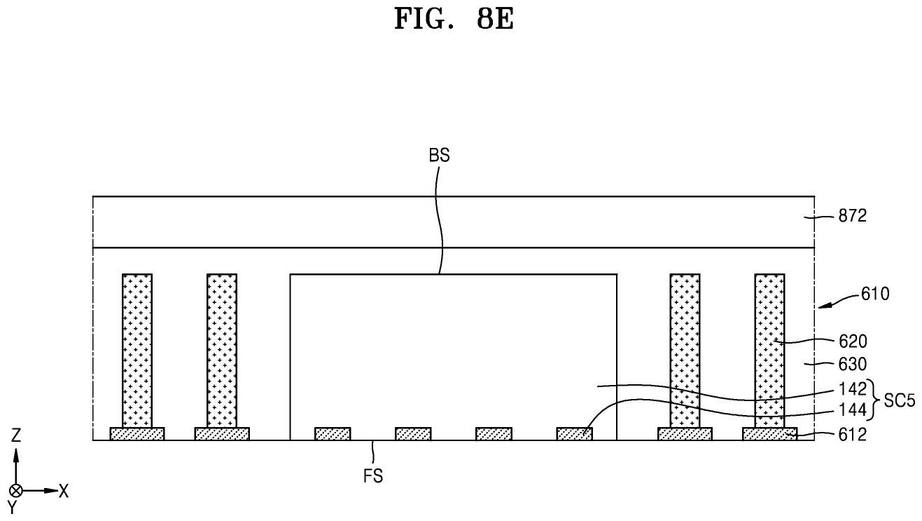

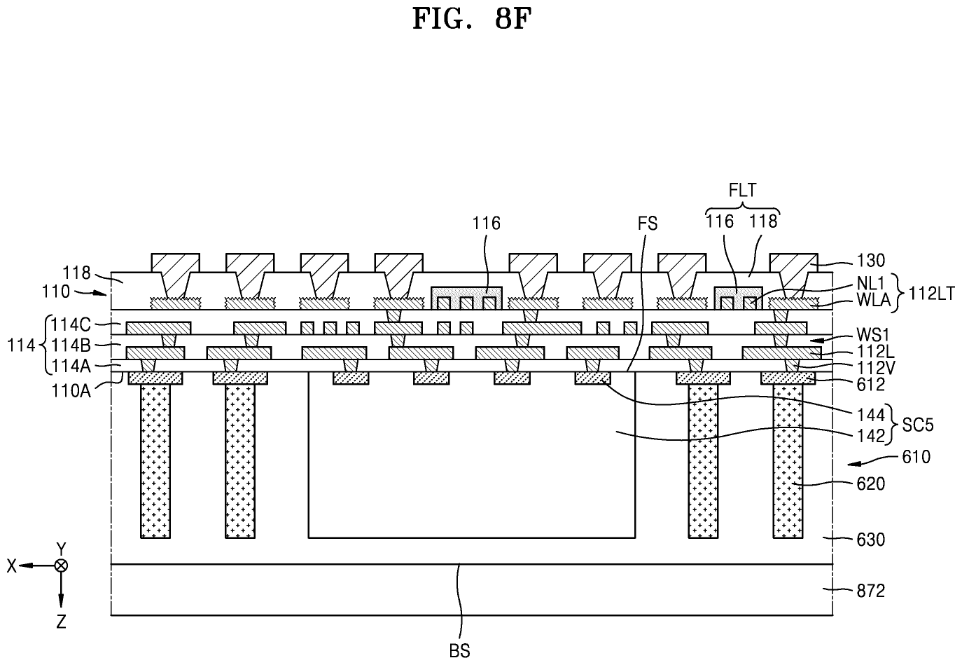

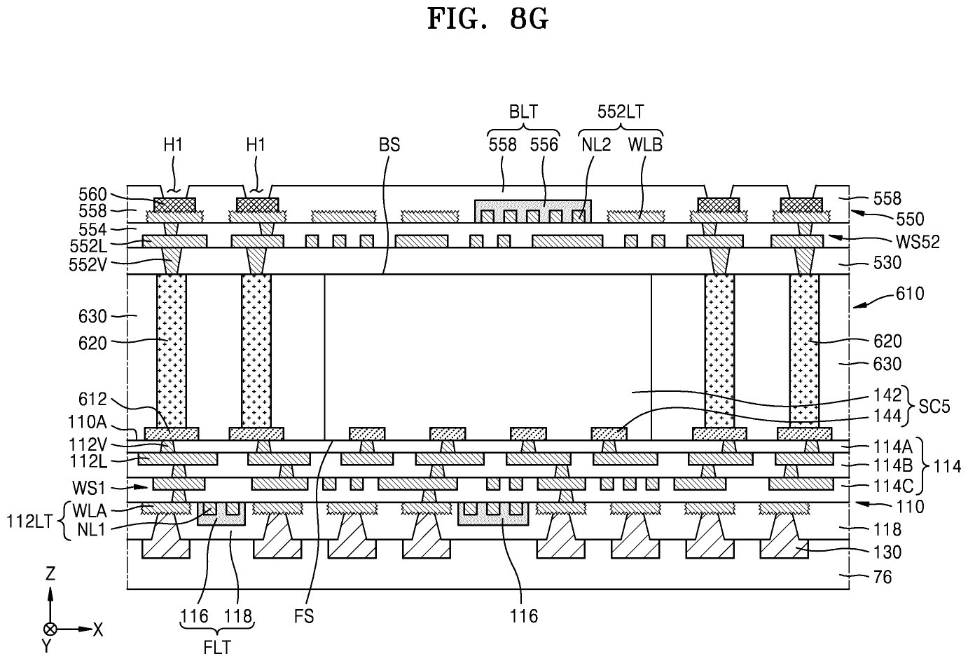

FIGS. 8A to 8G are cross-sectional views respectively illustrating a sequence of processes of a method of manufacturing a semiconductor package according to some embodiments of the present disclosure. An example of a method of manufacturing the semiconductor package 600 shown in FIG. 6 is described with reference to FIGS. 8A to 8G. In FIGS. 8A to 8G, the same reference numerals shown in FIGS. 1A, 1, 5, 6, and 7A to 7N respectively denote the same members, and here, repeated descriptions thereof are omitted.

Referring to FIG. 8A, a tape substrate 52, to which an adhesive layer 54 is attached, may be prepared, and copper foil 56 may be attached onto the adhesive layer 54. Next, a mask pattern MP1 may be formed on the copper foil 56, and a plurality of wiring patterns 58 may be formed on the copper foil 56 exposed by the mask pattern MP1.

In some embodiments, each of the tape substrate 52 and the adhesive layer 54 may include an organic material. For example, the tape substrate 52 may include polyimide. The mask pattern MP1 may include a photoresist pattern. To form the plurality of wiring patterns 58, an electroplating process using the copper foil 56 as an electrode may be performed.

Referring to FIG. 8B, the mask pattern MP1 may be removed from the resulting product of FIG. 8A, followed by forming a mask pattern MP2 having openings that expose respective portions of the plurality of wiring patterns 58, and then, the plurality of conductive posts 620 may be formed to respectively fill the openings.

In some embodiments, the mask pattern MP2 may include a photoresist pattern. To form the plurality of conductive posts 620, an electroplating process using the copper foil 56 as an electrode may be performed.

Referring to FIG. 8C, the mask pattern MP2 may be removed from the resulting product of FIG. 8B, and the copper foil 56 that is exposed as a result thereof may be etched. As a result, only portions of the copper foil 56, which are covered by the plurality of wiring patterns 58, may remain on the tape substrate 52. In some embodiments, a process of etching the copper foil 56 may be performed in a wet manner, but the present disclosure is not limited thereto. After the portions of the copper foil 56 are etched, the adhesive layer 54 may be exposed. A stack structure of the copper foil 56 and the wiring patterns 58, which remain on the tape substrate 52, may constitute wiring patterns 612. In the following figures and description, the stack structure of the copper foil 56 and the wiring patterns 58 is illustrated and described as corresponding to the wiring patterns 612.

Referring to FIG. 8D, in the resulting product of FIG. 8C, the semiconductor chip SC5 may be attached onto the exposed adhesive layer 54. The semiconductor chip SC5 may be arranged such that the active surface FS thereof, on which the plurality of chip pads 144 are arranged, faces the adhesive layer 54. Next, the molding layer 630 may be formed to cover the semiconductor chip SC5 and the plurality of conductive posts 620.

Referring to FIG. 8E, a first carrier substrate 872 may be attached onto the molding layer 630 of the resulting product of FIG. 8D. The first carrier substrate 872 may include one of a glass substrate, a silicon substrate, and a metal substrate. Next, the plurality of wiring patterns 612 and the plurality of chip pads 144 may be exposed by removing the adhesive layer 54 and the tape substrate 52.

Referring to FIG. 8F, in the resulting product of FIG. 8E, the frontside redistribution structure 110 and the plurality of conductive pads 130 may be formed on or over the plurality of wiring patterns 612 and the plurality of chip pads 144. To form the frontside redistribution structure 110 and the plurality of conductive pads 130, the processes as described with reference to FIGS. 7C to 7G may be performed.

Referring to FIG. 8G, the second carrier substrate 76 may be attached to the resulting product of FIG. 8F to cover the frontside redistribution structure 110 and the plurality of conductive pads 130, followed by removing the first carrier substrate 872, thereby exposing the molding layer 630.

Next, the backside redistribution structure 550 and the plurality of connection pads 560 may be formed on or over the molding layer 630. To form the backside redistribution structure 550 and the plurality of connection pads 560, similar processes to the processes described with reference to FIGS. 7H to 7M may be performed.

Next, in the resulting product of FIG. 8G, the plurality of connection terminals 570 may be formed to be respectively connected to the plurality of connection pads 560 exposed by the plurality of holes H1, followed by attaching the second package unit 580 onto the plurality of connection terminals 570, thereby forming the semiconductor package 600 shown in FIG. 6.

Although the examples of the methods of manufacturing the semiconductor packages 500 and 600 shown in FIGS. 5 and 6 have been described with reference to FIGS. 7A to 7N and 8A to 8G, it will be understood by those of ordinary skill in the art that, by making various modifications and changes to the examples described with reference to FIGS. 7A to 7N and 8A to 8G, the semiconductor packages 100, 200, 300, and 400 described with reference to FIGS. 1A to 4 or semiconductor packages having structures variously modified and changed therefrom without departing from the spirit and scope of the present disclosure may be manufactured.

While the present disclosure has been particularly shown and described with reference to embodiments thereof, it will be understood that various changes in form and details may be made therein without departing from the spirit and scope of the following claims.

1. A semiconductor package comprising:
a first package unit comprising a semiconductor chip; and
a redistribution structure on the first package unit,
wherein the redistribution structure comprises a plurality of wiring lines and a plurality of insulating layers on the plurality of wiring lines, wherein the plurality of wiring lines comprise a first subset including a plurality of outermost wiring lines and a second subset,
wherein a vertical distance between the plurality of outermost wiring lines and the first package unit is greater than a vertical distance between the second subset of the plurality of wiring lines and the first package unit,
a respective surface roughness of each of the plurality of outermost wiring lines is different, and
the respective surface roughness of each of the plurality of outermost wiring lines is based on a respective width of each of the plurality of outermost wiring lines in a horizontal direction.

2. The semiconductor package of claim 1, wherein the plurality of outermost wiring lines comprises a first wiring line portion comprising a first minimum width in the horizontal direction, and a second wiring line portion comprising a second minimum width in the horizontal direction that is greater than the first minimum width of the first wiring line portion, and
the respective surface roughness of at least a portion of the second wiring line portion is greater than a surface roughness of the first wiring line portion.

3. The semiconductor package of claim 1, wherein the plurality of outermost wiring lines comprise a first wiring line portion comprising a first minimum width of 10 μm or less in the horizontal direction, and a second wiring line portion comprising a second minimum width that is greater than 10 μm in the horizontal direction,
and wherein the respective surface roughness of the first wiring line portion is 0.1 μm or less, and the respective surface roughness of the second wiring line portion is greater than 0.1 μm and less than or equal to about 0.6 μm.

4. The semiconductor package of claim 1, wherein the plurality of outermost wiring lines comprise a first wiring line portion comprising a first surface having a first surface roughness, and a second wiring line portion comprising a second surface having a second surface roughness that is greater than the first surface roughness of the first surface of the first wiring line portion,
the plurality of insulating layers comprise an outermost insulating layer on the plurality of outermost wiring lines,
wherein the outermost insulating layer comprises:
a local insulating pattern that contacts the first surface of the first wiring line portion and does not contact the second surface of the second wiring line portion; and
an outer insulating pattern, wherein the local insulating pattern is between the first wiring line portion and the outer insulating pattern, the outer insulating pattern contacts the second surface of the second wiring line portion, and
the local insulating pattern and the outer insulating pattern comprise different materials.

5. The semiconductor package of claim 4, wherein the local insulating pattern contacts the outer insulating pattern,
the local insulating pattern comprises a photo-imageable dielectric (PID) material layer or a solder resist (SR) layer, and
the outer insulating pattern comprises at least one of Ajinomoto Build-up Film (ABF), the SR layer, the PID material layer, and an epoxy molding compound (EMC).

6. The semiconductor package of claim 4, wherein the local insulating pattern contacts the outer insulating pattern,
the local insulating pattern comprises at least one of polyhydroxyamide (PHA), polybenzoxazole (PBO), polyamic acid (PAA), polyimide (PI), a benzocyclobutene (BCB)-based polymer, bisphenol A (BPA) epoxy, and novolac epoxy, and
the outer insulating pattern comprises at least one of PHA, PBO, PAA, PI, a BCB-based polymer, BPA epoxy, and novolac epoxy.

7. The semiconductor package of claim 1, wherein the plurality of outermost wiring lines comprise at least one narrow wiring line portion comprising a first minimum width in the horizontal direction, and a plurality of wide wiring line portions comprising a second minimum width in the horizontal direction that is greater than the first minimum width of the at least one narrow wiring line portion,
the plurality of wide wiring line portions comprise a first wide wiring line portion that is adjacent to the at least one narrow wiring line portion in the horizontal direction, and a second wide wiring line portion that is integrally connected to the first wide wiring line portion, wherein the first wide wiring line portion is between the at least one narrow wiring line portion and the second wide wiring line portion, and
the respective surface roughness of the second wide wiring line portion is greater than the respective surface roughness of the first wide wiring line portion.

8. The semiconductor package of claim 7, wherein the plurality of insulating layers comprise an outermost insulating layer on the plurality of outermost wiring lines,
wherein the outermost insulating layer comprises:
a local insulating pattern that contacts a surface of the at least one narrow wiring line portion and a surface of the first wide wiring line portion; and
an outer insulating pattern, wherein the local insulating pattern is between the at least one narrow wiring line portion and the outer insulating pattern, wherein the outer insulating pattern contacts a surface of the second wide wiring line portion, and
the local insulating pattern and the outer insulating pattern comprise different materials from each other.

9. The semiconductor package of claim 1, further comprising a conductive pad that is connected to one outermost wiring line selected from the plurality of outermost wiring lines,
wherein the plurality of outermost wiring lines comprise a first wiring line portion comprising a first surface having a first surface roughness, and a second wiring line portion comprising a second surface having a second surface roughness that is greater than the first surface roughness of the first surface of the first wiring line portion, and
the conductive pad contacts the second surface of the second wiring line portion and does not contact the first surface of the first wiring line portion.

10. The semiconductor package of claim 1, further comprising:
a connection pad that is connected to one outermost wiring line selected from the plurality of outermost wiring lines;
a connection terminal connected to the connection pad; and
a second package unit that is connected to the one outermost wiring line via the connection terminal and the connection pad,
wherein the plurality of outermost wiring lines comprise a first wiring line portion comprising a first surface having a first surface roughness, and a second wiring line portion comprising a second surface having a second surface roughness that is greater than the first surface roughness of the first surface of the first wiring line portion, and
the connection pad contacts the second surface of the second wiring line portion and does not contact the first surface of the first wiring line portion.

11. The semiconductor package of claim 1, wherein the second subset of wiring lines further comprise a plurality of inner wiring lines,
the respective surface roughness of each of the plurality of inner wiring lines is 0.1 μm or less, and
the plurality of outermost wiring lines comprise a first wiring line portion comprising a first width of 10 μm or less in the horizontal direction, and a second wiring line portion comprising a second width that is greater than 10 μm in the horizontal direction, the respective surface roughness of the first wiring line portion is 0.1 μm or less, and the respective surface roughness of the second wiring line portion having a value that is greater than 0.1 μm and less than or equal to about 0.6 μm.

12. A semiconductor package comprising:
a package unit comprising a semiconductor chip that comprises a first surface and a second surface that is opposite to the first surface;
a frontside redistribution structure on the first surface of the semiconductor chip; and
a backside redistribution structure on the second surface of the semiconductor chip,
wherein each of the frontside redistribution structure and the backside redistribution structure comprises:
a plurality of wiring lines and a plurality of insulating layers on the plurality of wiring lines, wherein the plurality of wiring lines comprise a first subset comprising a plurality of outermost wiring lines and a second subset, wherein a vertical distance between the plurality of outermost wiring lines and the package unit is greater than a vertical distance between the second subset of the plurality of wiring lines and the package unit,
a respective surface roughness of each of the plurality of outermost wiring lines is different, and
the respective surface roughness of each of the plurality of outermost wiring lines is based on a respective width of each of the plurality of outermost wiring lines in a horizontal direction.

13. The semiconductor package of claim 12, wherein the plurality of outermost wiring lines comprises a first wiring line portion that comprises a first width of 10 μm or less in the horizontal direction, and a second wiring line portion that comprises a second width that is greater than 10 μm in the horizontal direction,
and wherein the respective surface roughness of the first wiring line portion is 0.1 μm or less, and the respective surface roughness of the second wiring line portion is greater than 0.1 μm and less than or equal to about 0.6 μm.

14. The semiconductor package of claim 12, wherein the plurality of outermost wiring lines comprise a first wiring line portion that comprises a first surface comprising a first surface roughness, and a second wiring line portion that comprises a second surface comprising a second surface roughness,
for each of the frontside redistribution structure and the backside redistribution structure, the plurality of insulating layers comprise an outermost insulating layer on the plurality of outermost wiring lines, and
the outermost insulating layer comprises:
a local insulating pattern that contacts the first surface of the first wiring line portion and does not contact with the second surface of the second wiring line portion; and
an outer insulating pattern, wherein the local insulating pattern is between the first wiring line portion and the outer insulating pattern, the outer insulating pattern contacts the second surface of the second wiring line portion, and
the local insulating pattern and the outer insulating pattern comprise different materials.

15. The semiconductor package of claim 12, wherein, for each of the frontside redistribution structure and the backside redistribution structure, the plurality of insulating layers comprise an outermost insulating layer on the plurality of outermost wiring lines,
the plurality of outermost wiring lines comprise:
a first wiring line portion comprising a first minimum width of 10 μm or less in the horizontal direction and a first surface comprising a first surface roughness; and
a second wiring line portion comprising a second minimum width that is greater than 10 μm in the horizontal direction and a second surface comprising a second surface roughness that is greater than the first surface roughness of the first surface of the first wiring line portion, and
the outermost insulating layer comprises:
a local insulating pattern that contacts the first surface of the first wiring line portion and does not contact the second surface of the second wiring line portion; and
an outer insulating pattern, wherein the local insulating pattern is between the outer insulating pattern and the first wiring line portion, and the outer insulating pattern contacts the second surface of the second wiring line portion, and
the local insulating pattern and the outer insulating pattern comprise different materials.

16. The semiconductor package of claim 15, wherein the local insulating pattern contacts the outer insulating pattern,
the local insulating pattern comprises a photo-imageable dielectric (PID) material layer or a solder resist (SR) layer, and
the outer insulating pattern comprises at least one of Ajinomoto Build-up Film (ABF), the SR layer, the PID layer, and an epoxy molding compound (EMC).

17. The semiconductor package of claim 12, wherein the plurality of outermost wiring lines comprise at least one narrow wiring line portion that comprises a first minimum width in the horizontal direction, and a plurality of wide wiring line portions that each comprises a second minimum width in the horizontal direction that is greater than the first minimum width of the at least one narrow wiring line portion,
the plurality of wide wiring line portions comprise a first wide wiring line portion that is adjacent to the at least one narrow wiring line portion in the horizontal direction, and a second wide wiring line portion that is integrally connected to the first wide wiring line portion,
wherein the first wide wiring line portion is between the at least one narrow wiring line portion, and
the respective surface roughness of the second wide wiring line portion is greater than the respective surface roughness of the first wide wiring line portion.

18. A semiconductor package comprising:
a first package unit comprising a semiconductor chip that comprises an active surface and an inactive surface that is opposite to the active surface;
a frontside redistribution structure on the active surface of the semiconductor chip;
a backside redistribution structure on the inactive surface of the semiconductor chip; and
a second package unit on the backside redistribution structure,
wherein at least one of the frontside redistribution structure and the backside redistribution structure comprises:
a plurality of wiring lines and a plurality of insulating layers on the plurality of wiring lines, wherein the plurality of wiring lines comprise a plurality of outermost wiring lines and a plurality of inner wiring lines, wherein a vertical distance between the plurality of outermost wiring lines and the first package unit is greater than a vertical distance between the plurality of inner lines and the first package unit,
a respective surface roughness of each of the plurality of inner wiring lines is independent of a respective width of the plurality of inner wiring lines in a horizontal direction, and
a respective surface roughness of each of the plurality of outermost wiring lines is based on a respective width of each of the plurality of outermost wiring lines in the horizontal direction.

19. The semiconductor package of claim 18, wherein the plurality of outermost wiring lines comprise a first wiring line portion that comprises a first width of 10 μm or less in the horizontal direction, and a second wiring line portion that comprises a second width that is greater than 10 μm in the horizontal direction,
and wherein the respective surface roughness of the first wiring line portion is 0.1 μm or less, the respective surface roughness of the second wiring line portion is greater than 0.1 μm and less than or equal to about 0.6 μm, and the surface roughness of each of the plurality of inner wiring lines is 0.1 μm or less.

20. The semiconductor package of claim 19, wherein the plurality of insulating layers comprise:
an outermost insulating layer that comprises a double-layer structured portion on the first wiring line portion and a single-layer structured portion on the second wiring line portion; and
an inner insulating layer between the first package unit and the outermost insulating layer and on the plurality of inner wiring lines, the inner insulating layer comprising a single layer,
the double-layer structured portion of the outermost insulating layer comprises a local insulating pattern that comprises a photo-imageable dielectric (PID) material layer or a solder resist (SR) layer, the double-layer structured portion of the outermost insulating layer comprises an outer insulating pattern that comprises at least one selected from Ajinomoto Build-up Film (ABF), an SR, a PID, and an epoxy molding compound (EMC),
the single-layer structured portion of the outermost insulating layer comprises at least one of the ABF, the SR layer, the PID layer, and the EMC, and
the inner insulating layer comprises at least one of the PID layer, the ABF, the SR layer, and the EMC.

21.-30. (canceled)
